(19) United States
(12) Patent Application Publication
(10) Pub. No.: US 2025/0341574 A1
(43) Pub. Date: Nov. 6, 2025

(54) MECHANIZED IRRIGATION MACHINE THAT USES ELECTRICAL CHARACTERISTICS TO FIND AN OPEN SWITCH OR WIRE

(71) Applicant: Lindsay Corporation, Omaha, NE (US)

(72) Inventors: Luke Joseph Barker, Omaha, NE (US); Bradford L. Ellison, Omaha, NE (US); Mark William Miller, Omaha, NE (US); Robert Stamm, Omaha, NE (US)

(21) Appl. No.: 18/775,996

(22) Filed: Jul. 17, 2024

Related U.S. Application Data
(60) Provisional application No. 63/641,613, filed on May 2, 2024.

(51) Int. Cl. G01R 31/327; A01G 25/02; G01R 19/10; G01R 31/08

(52) U.S. Cl. CPC G01R 31/3274; G01R 19/10; G01R 31/08; G01R 31/3275; A01G 25/02

(57) ABSTRACT

An irrigation system comprises a plurality of towers and a central controller. At least a portion of the towers includes a successive one of a plurality of safety switches, with each safety switch being either closed or open. The safety switch of each tower is electrically connected to at least one safety switch of another tower. The central controller is electrically connected to at least one of the safety switches and is configured to measure a differential voltage between a safety switch circuit load formed in part by the safety switches and a reference load, and determine, according to the differential voltage, at least one of a location of the open safety switch and an identifier of the tower associated with the open safety switch.

### CROSS-REFERENCE TO RELATED APPLICATIONS

The current patent application is a non-provisional utility patent application which claims priority benefit, with regard to all common subject matter, of earlier-filed U.S. Provisional Application Ser. No. 63/641,613; titled “MECHANIZED IRRIGATION MACHINE THAT USES ELECTRICAL CHARACTERISTICS TO FIND AN OPEN SWITCH OR WIRE”; and filed May 2, 2024. The Provisional Application is hereby incorporated by reference, in its entirety, into the current patent application.

### FIELD OF THE INVENTION

Embodiments of the current invention relate to mechanized irrigation systems that include a plurality of safety switches.

### BACKGROUND OF THE INVENTION

Mechanized irrigation systems comprise a plurality of spaced-apart, motorized, and self-propelled towers which support a fluid-carrying conduit and sprayer system that sprays the fluid on one or more crops. In a center-pivot irrigation system, the conduit is coupled to a fluid source at a center pivot point, and the towers travel in a roughly circular path around the center pivot. Between each adjacent pair of towers is a successive one of a plurality of sections of the conduit, wherein each adjacent pair of conduit sections is coupled with a successive one of a plurality of joints that is flexible. The towers travel independently of one another and may travel at different speeds and at different times. Thus, during normal operation, the towers may travel such that there is a non-zero alignment angle between adjacent sections of the conduit. Some variation of the alignment angle, both positive and negative, is acceptable. However, for numerous reasons the alignment angle may exceed a safe threshold. To monitor the alignment angle, each tower includes a safety switch coupled to the conduit on each adjacent section. The safety switch will open if the alignment angle between the two associated sections of conduit exceeds the safe threshold. A central controller, which controls the operation of the irrigation system, senses the open switch and shuts down the operation of the irrigation system. The central controller may also transmit an error message which alerts a technician to attend the irrigation system and repair, replace, or reposition the tower which has caused the alignment error that opened the safety switch. A problem may arise with irrigation systems that include dozens of towers and may be thousands of feet long. It may be difficult to determine which tower has the problem.

### SUMMARY OF THE INVENTION

Embodiments of the current invention address one or more of the above-mentioned problems and provide irrigation systems that measure changes in the electrical characteristics of a safety switch circuit to detect an open safety switch and determine an identifier and/or a location of the tower associated with the open safety switch. Specifically, the safety switch circuit includes a plurality of electrical components which form a safety switch circuit load by default. A reference load, also formed from electrical components, is connected to the safety switch circuit to create a bridge circuit, which makes it easy to compare the safety switch circuit load to the reference load. When one of the safety switches opens, the electrical characteristics of the safety switch circuit load change as compared to the reference load. The change can be measured. The magnitude of the change is indicative of the identifier and/or the location of the tower associated with the open safety switch.

One embodiment of the irrigation system broadly comprises a plurality of towers and a central controller. At least a portion of the towers includes a successive one of a plurality of safety switches, with each safety switch being either closed or open. The safety switch of each tower is electrically connected to at least one safety switch of another tower. The central controller is electrically connected to at least one of the safety switches and is configured to measure a differential voltage between a safety switch circuit load formed in part by the safety switches and a reference load, and determine, according to the differential voltage, at least one of a location of the open safety switch and an identifier of the tower associated with the open safety switch.

Another embodiment of the current invention provides an irrigation system broadly comprising a plurality of towers and a central controller. At least a portion of the towers includes a successive one of a plurality of safety switches, with each safety switch being either closed or open. The safety switch of each tower is electrically connected to at least one safety switch of another tower. The central controller is electrically connected to at least one of the safety switches. The central controller includes, or is in electronic communication with, a differential voltage measurement circuit comprising a voltage source configured to output a varying voltage; a safety switch circuit load formed in part by the safety switches, a reference load, and two resistors electrically connected to one another to form a bridge circuit that is electrically connected to the voltage source; and a voltmeter configured to measure a differential voltage from a first point between the safety switch circuit load and a first resistor to a second point between the reference load and a second resistor. The central controller further includes a processor configured to determine, according to the differential voltage, at least one of a location of the open safety switch and an identifier of the tower associated with the open safety switch.

Yet another embodiment of the current invention provides a method for determining a position of an open safety switch in an irrigation system that includes a plurality of towers, with at least a portion of the towers including a successive one of a plurality of safety switches. The method broadly comprises positioning an impedance cable in proximity to a safety switch cable that electrically connects the safety switches to one another to form a safety switch circuit; applying an alternating current (AC) voltage to the safety switch circuit and a reference load; measuring a differential voltage between a voltage drop across the safety switch circuit and a voltage drop across the reference load; and determining the position of an open safety switch according to the differential voltage.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current invention will be apparent from the following detailed description of the embodiments and the accompanying drawing figures.

### BRIEF DESCRIPTION OF DRAWINGS

Embodiments of the current invention are described in detail below with reference to the attached drawing figures, wherein:

FIG. 1 is a perspective environmental view of an irrigation system, constructed in accordance with various embodiments of the current invention, including a plurality of towers and a plurality of safety switches, each safety switch associated with a successive one of the towers, the irrigation system configured to determine a location or an identifier of an open safety switch;

FIG. 2 is a schematic block diagram of an electrical connection of the safety switches, a central controller, and a differential voltage measurement circuit;

FIG. 3 is a schematic block diagram of the electrical components of a first embodiment of the differential voltage measurement circuit;

FIG. 4A is a first plot of differential voltage vs. a tower number having an open safety switch;

FIG. 4B is a second plot of differential voltage vs. a tower number having an open safety switch;

FIG. 5 is a schematic block diagram of the electrical components of a second embodiment of the differential voltage measurement circuit;

FIG. 6 is a schematic block diagram of the electrical components of a third embodiment of the differential voltage measurement circuit;

FIG. 7 is a listing of at least a portion of the steps of a method of determining a position of an open safety switch in an irrigation system;

FIG. 8 is a schematic block diagram of the electrical components of an alternative of the first embodiment of the differential voltage measurement circuit;

FIG. 9 is a schematic block diagram of the electrical components of an alternative of the second embodiment of the differential voltage measurement circuit;

FIG. 10 is a schematic block diagram of the electrical components of an alternative of the third embodiment of the differential voltage measurement circuit;

FIG. 11 is a listing of at least a portion of the steps of another method of determining a position of an open safety switch in an irrigation system;

FIG. 12 is a schematic block diagram of an electrical connection of the safety switches, the central controller, and a safety switch measurement circuit;

FIG. 13 is a schematic block diagram of the safety switch measurement circuit;

FIG. 14 is a schematic diagram of one embodiment of the safety switch measurement circuit and the safety switch circuit; and

FIG. 15 is a schematic block diagram of another embodiment of the safety switch measurement circuit.

The drawing figures do not limit the current invention to the specific embodiments disclosed and described herein. The drawings are not necessarily to scale, emphasis instead being placed upon clearly illustrating the principles of the invention.

### DETAILED DESCRIPTION OF THE INVENTION

The following detailed description of the technology references the accompanying drawings that illustrate specific embodiments in which the technology can be practiced. The embodiments are intended to describe aspects of the technology in sufficient detail to enable those skilled in the art to practice the technology. Other embodiments can be utilized and changes can be made without departing from the scope of the current invention. The following detailed description is, therefore, not to be taken in a limiting sense. The scope of the current invention is defined only by the appended claims, along with the full scope of equivalents to which such claims are entitled.

In the following description, the word “voltage” may be used to describe electric voltage, the word “current” may be used to describe electric current, and the word “power” may be used to describe electric power. In addition, the word “signal” may be used to describe an electromagnetic wave conducted through an electrically conductive medium in which a voltage and/or a current varies, or may be constant, over time.

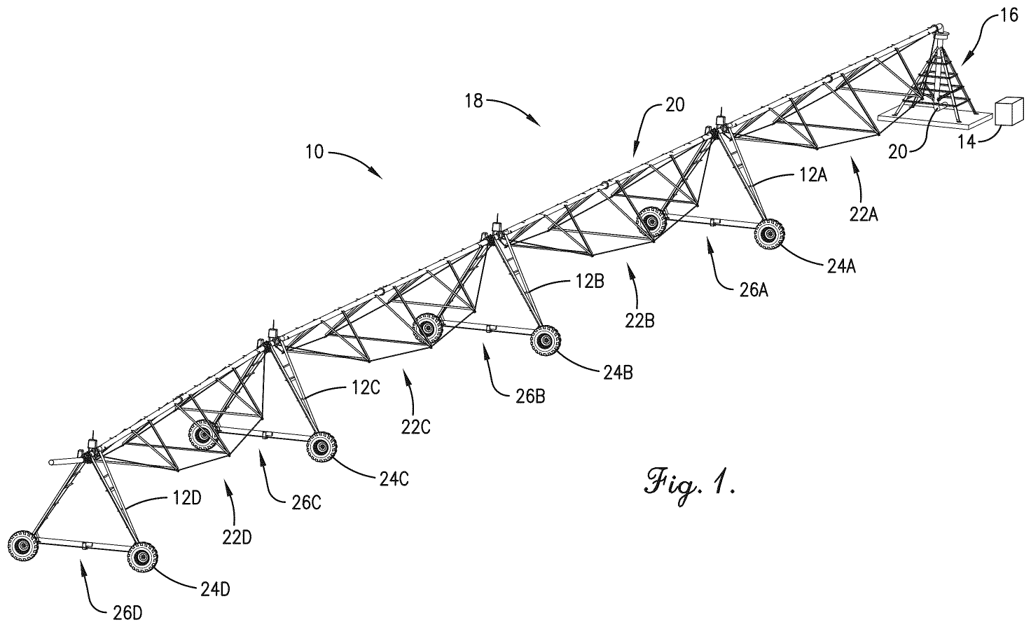

A mechanized irrigation system 10, constructed in accordance with various embodiments of the current invention, is shown in FIG. 1. The irrigation system 10 broadly comprises a plurality of towers 12 which support fluid delivery components along with a central controller 14 that controls operation of the irrigation system 10. An exemplary embodiment of the irrigation system 10, shown in FIG. 1, is a center pivot irrigation system and broadly comprises a fixed center pivot 16 and a main section 18 pivotally connected to the center pivot. The irrigation system 10 may also comprise an extension arm (also commonly referred to as a “swing arm” or “corner arm”) pivotally connected to the free end of the main section 18. The irrigation system 10 may also be embodied by a lateral, or linear, move apparatus which irrigates while moving in a linear, or near-linear, direction without departing from the scope of the current invention.

The fixed center pivot 16 may be a tower or any other support structure about which the main section 18 may pivot. The center pivot has access to a well, water tank, or other source of water or other fluid and may also be coupled with a tank or other source of agricultural products to inject fertilizers, pesticides and/or other chemicals into the water for application during irrigation. The center pivot 16 may supply water to a conduit 20 which carries the water along the length of the main section 18.

The main section 18 may comprise any number of mobile support towers 12A-D, the outermost tower 12D of which is referred to herein as an end tower. The towers 12A-D are connected to the fixed center pivot 16 and to one another by truss sections 22A-D or other supports to form a number of interconnected spans.

The towers 12 have wheels 24A-D, at least one of which is driven by suitable drive motors 26A-D. Each motor 26A-D turns at least one of its wheels 24A-D through a drive shaft to propel its tower 12 and thus the main section 18 in a circle about the center pivot 16 to irrigate a field. The motors 26 may also have several speeds or be equipped with variable speed drives. The operation of the motors 26A-D, such as whether they are on or off, the speed of travel, and the direction of travel, may be controlled with one or more electronic signals or digital data.

Each of the truss sections 22A-D carries or otherwise supports the conduit 20 and other fluid distribution mechanisms that are connected in fluid communication to the conduit 20. Fluid distribution mechanisms may include sprayers or diffusers, each optionally attached to a drop hose, or the like. Between each adjacent pair of towers 12A-D is a successive one of a plurality of sections of the conduit 20, wherein each adjacent pair of conduit 20 sections is coupled with a successive one of a plurality of joints that is flexible. In addition, the conduit 20 may include one or more valves which control the flow of water through the conduit 20. The opening and closing of the valves may be automatically controlled with an electronic signal or digital data.

The irrigation system 10 may also include wired or wireless communication electronic components that communicate with a communication network and allow the valves and the motors 26 to receive the electronic signals and/or digital data which control the operation of the valves and the motors 26.

The irrigation system 10 may also include an optional extension arm (not shown) pivotally connected to the end tower 12D and may be supported by a swing tower 12 with steerable wheels 24 driven by a motor 26. The extension arm may be joined to the end tower 12D by an articulating pivot joint. The extension arm is folded in relative to the end tower 12D when it is not irrigating a corner of a field and may be pivoted outwardly away from the end tower 12D while irrigating the corners of a field.

The irrigation system 10 illustrated in FIG. 1 has four towers 12A-D; however, it may comprise any number of towers, truss sections, wheels, and drive motors without departing from the scope of the current invention.

The irrigation system 10 may further include one or more sensors which measure the amount of water delivered from the irrigation system 10 to the crop. The sensors may communicate with the communication network to report the amount of delivered water. The water may be reported as a depth in units of millimeters (mm) or inches (in).

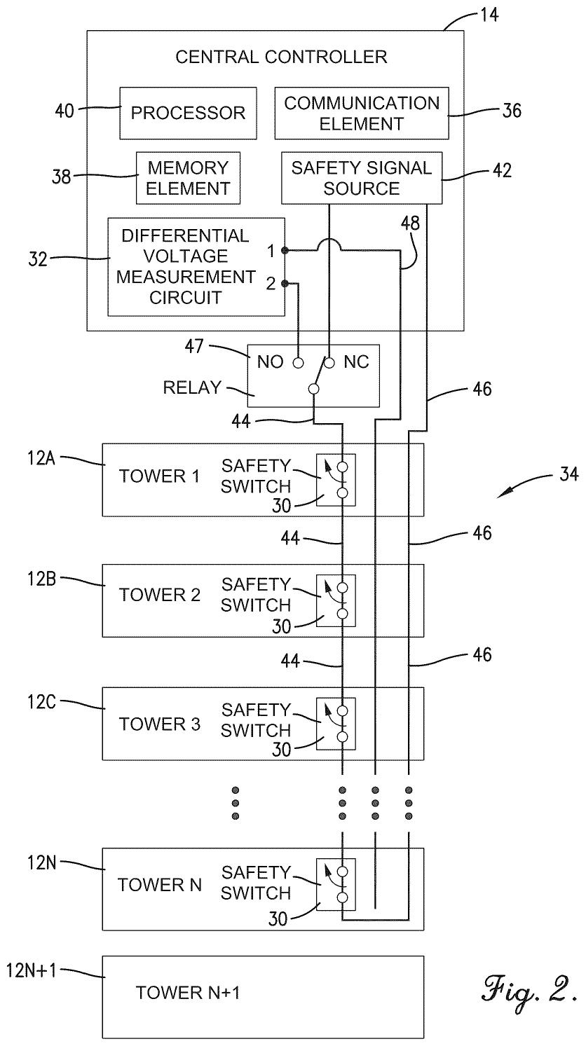

The irrigation system 10 further includes a plurality of safety switches 30, with each safety switch 30 being positioned at, and associated with, a successive one of the towers 12 and coupled to the two adjacent sections of the conduit 20 that are joined at the tower 12, although the last tower 12D (in FIG. 1), 12N+1 (in FIG. 2) typically does not have a safety switch 30. Each safety switch 30 monitors an alignment angle between one section of the conduit 20 and its adjacent inward section of the conduit 20. The safety switch 30 opens when its associated tower 12 moves its section of conduit 20 into an unsafe alignment or position, which, in turn, leads to the central controller 14 shutting down operation of the irrigation system 10. While the exemplary irrigation system 10 in FIG. 1 includes four towers 12, real world irrigation systems 10 may include up to a couple of dozen towers 12. Thus, it is helpful to a technician who has to restore or repair the irrigation system 10 to know which tower 12 has the problem. To assist the technician, the central controller 14 of the irrigation system 10 also includes, or is in electronic communication with, a differential voltage measurement circuit 32 which is configured to identify the tower 12 that is in need of repair.

Referring to FIG. 2, a configuration of the central controller 14, the safety switches 30, the differential voltage measurement circuit 32, and a safety switch circuit 34 is shown. The central controller 14 generally controls the operation of the irrigation system 10 and broadly comprises a communication element 36, a memory element 38, a processor 40, and a safety signal source 42.

The communication element 36 generally allows the central controller 14 to communicate with external systems, computing networks, telecommunication networks, the Internet, and the like. The communication element 36 may include signal and/or data transmitting and receiving circuits, such as antennas, amplifiers, filters, mixers, oscillators, digital signal processors (DSPs), and the like. The communication element 36 may establish communication wirelessly by utilizing radio frequency (RF) signals and/or data that comply with communication standards such as cellular 2G, 3G, 4G, Voice over Internet Protocol (VoIP), LTE, Voice over LTE (VOLTE), or 5G, Institute of Electrical and Electronics Engineers (IEEE) 802.11 standard such as WiFi, IEEE 802.16 standard such as WiMAX, Bluetooth™, or combinations thereof. In addition, the communication element 36 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 36 may establish communication through connectors or couplers that receive metal conductor wires or cables which are compatible with networking technologies such as ethernet. In certain embodiments, the communication element 36 may also couple with optical fiber cables. The communication element 36 may be in electronic communication with the memory element 38 and the processor 40.

The memory element 38 may be embodied by devices or components that store data in general, and digital or binary data in particular, and may include exemplary electronic hardware data storage devices or components such as read-only memory (ROM), programmable ROM, erasable programmable ROM, random-access memory (RAM) such as static RAM (SRAM) or dynamic RAM (DRAM), cache memory, hard disks, floppy disks, optical disks, flash memory, thumb drives, universal serial bus (USB) drives, solid state memory, or the like, or combinations thereof. In some embodiments, the memory element 38 may be embedded in, or packaged in the same package as, the processor 40. The memory element 38 may include, constitute, or embody, a non-transitory “computer-readable medium”. The memory element 38 may store the instructions, code, code statements, code segments, software, firmware, programs, applications, apps, services, daemons, or the like that are executed by the processor 40. The memory element 38 is in electronic communication with the processor 40 and may also store data that is received by the processor 40 or the device in which the processor 40 is implemented. The processor 40 may further store data or intermediate results generated during processing, calculations, and/or computations as well as data or final results after processing, calculations, and/or computations. In addition, the memory element 38 may store settings, text data, documents from word processing software, spreadsheet software and other software applications, sampled audio sound files, photograph or other image data, movie data, databases, and the like.

The processor 40 may comprise one or more processors that include electronic hardware components such as microprocessors (single-core or multi-core), microcontrollers, digital signal processors (DSPs), field-programmable gate arrays (FPGAs), analog and/or digital application-specific integrated circuits (ASICs), intelligence circuitry, or the like, or combinations thereof. The processor 40 may generally execute, process, or run instructions, code, code segments, code statements, software, firmware, programs, applications, apps, processes, services, daemons, or the like. The processor 40 may also include hardware components such as registers, finite-state machines, sequential and combinational logic, configurable logic blocks, and other electronic circuits that can perform the functions necessary for the operation of the current invention. In certain embodiments, the processor 40 may include multiple computational components and functional blocks that are packaged separately but function as a single unit. In some embodiments, the processor 40 may further include multiprocessor architectures, parallel processor architectures, processor clusters, and the like, which provide high performance computing. The processor 40 may be in electronic communication with the other electronic components of the central controller 14 through serial or parallel links that include universal busses, address busses, data busses, control lines, and the like. In addition, the processor 40 may include analog to digital converters (ADCs) to convert analog electronic signals to (streams of) digital data values and/or digital to analog converters (DACs) to convert (streams of) digital data values to analog electronic signals.

The processor 40 is operable, configured, and/or programmed to perform the functions, operations, processes, methods, and/or algorithms of the central controller 14 by utilizing hardware, software, firmware, or combinations thereof. Other components, such as the communication element 36 and the memory element 38 may be utilized as well. The central controller 14 may also have access to, and be in electronic communication with, cloud computing services, wherein a portion of the functions, operations, processes, methods, and/or algorithms of the central controller 14 are performed by computing resources off-site. Additionally, or alternatively, the processor 40 may include components, such as cloud computing components, that are physically located in a plurality of different geolocations. The components are able to communicate with each other to provide cohesive operation.

The processor 40 generally controls the operation of the irrigation system 10 by receiving data from sensors and other components and by outputting control signals to the valves and drive motors 26. The data from the sensors may include data about the amount of water that is being delivered to the crops. As a result, the processor 40 may output signals to the valves to control the flow of water and to the drive motors 26 to control the speed of travel of the towers 12 according to the values of the data.

The processor 40 may also receive a status signal from the safety signal source 42. If the status signal indicates that the safety signal is being received, then the processor 40 takes no specific action. If the status signal indicates that the safety signal is not being received, then the processor 40 may delay for a short period of time in case one of the safety switches 30 momentarily opened and then closed again. After the delay, the processor 40 may halt operation of the irrigation system 10 by terminating the flow of water and stopping the movement of the towers 12.

The processor 40 may output a control signal, including a voltage level or data, to the differential voltage measurement circuit 32 which instructs the differential voltage measurement circuit 32 to output a measurement signal and measure a differential voltage, as described in more detail below. The processor 40 outputs the control signal to the differential voltage measurement circuit 32 when the processor 40 determines, or receives indication of, the safety signal is no longer being received.

In some embodiments, the differential voltage measurement circuit 32 may output a differential voltage signal which includes a voltage or data value that varies according to the measured differential voltage. The processor 40 receives the differential voltage signal and determines a position, including an identification, such as a numerical value representing the order, of the tower 12 with the open safety switch 30 and/or a distance from the center pivot 16 to the tower 12 with the open safety switch 30. The processor 40 may determine the identification of, and/or the distance to, the tower 12 with the open safety switch 30 by solving a mathematical equation that calculates the identification and/or distance as a function of the content of the differential voltage signal. Additionally, or alternatively, the processor 40 may determine the identification of, and/or the distance to, the tower 12 with the open safety switch 30 by querying a lookup table. The lookup table may include a listing of tower identifications, wherein each tower identification is associated with a range of values, of the voltage or data, of the differential voltage signal. Or, the lookup table may include a listing of a plurality of distances outward from the center pivot 16. The distances may include a distance from the center pivot 16 to each tower 12. Or the distances may include a plurality of intermediate distances as well. Each distance is associated with a range of values, of the voltage or data, of the differential voltage signal. Additionally, or alternatively, the processor 40 may determine a location (or geolocation) of the open safety switch 30 which varies according to the value, of the voltage or data, of the differential voltage signal.

In other embodiments, the differential voltage measurement circuit 32 may output the differential voltage signal which includes a voltage or data value that varies according to the identification of, and/or the distance to, the tower 12 with the open safety switch 30-which the differential voltage measurement circuit 32 determines itself.

The processor 40 may in addition output a message, that is transmitted through the communication element 36, indicating that one of the safety switches 30 has opened and the irrigation system 10 has shut down. The message may also indicate the number of, identification of, location of, or distance to, the tower 12 with the open safety switch 30. The message may be received by an external receiver, such as an operations center, an owner of the property, a technician who maintains the irrigation system 10, or combinations thereof. Alternatively, or additionally, the central controller 14 may include a display at the center pivot which displays the message.

The safety signal source 42 generally outputs and receives an electronic safety signal and senses when the safety signal is not received.

Each safety switch 30 is embodied by a single-pole, single-throw (SPST) type switch, or any type of switch that includes a first terminal and a second terminal with a moveable contact providing electrical connection between the terminals in a closed position and no electrical connection in an open position. The safety switch 30 is closed when the alignment angle between the two sections of the conduit 20 joined at the associated tower 12 is below or equal to a safety threshold value and open when alignment angle is above the safety threshold value. The safety switch 30 may be implemented as a limit switch that is integrated in a mechanical assembly which includes a rotating cam mechanically coupled to the conduit 20 at the joint where two sections of the conduit 20 are connected. The cam rotates in response to the rotation of the outward section of the conduit 20 with respect to the inward section of the conduit 20, and thus the angular position of the cam represents the alignment angle between the two sections of the conduit 20. An exemplary embodiment of the safety switch 30 assembly is described in U.S. Pat. No. 9,538,712, which is hereby incorporated by reference, in its entirety, into the current patent application, except where inconsistent with the teachings of the current patent application. Rotation of the cam beyond the safety threshold angle, in either the clockwise direction or the counter clockwise direction, opens the safety switch 30.

Each of the safety switches 30 is electrically connected to the safety signal source 42 through a switch cable 44 and a return cable 46, as shown in FIG. 2. The switch cable 44 includes a plurality of sections, wherein a first section electrically connects the first port of the safety signal source 42 to the safety switch 30 at the first tower 12A. A successive one of other sections of the switch cable 44 electrically connects each successive adjacent pair of safety switches 30 to one another so that all of the safety switches 30 are electrically connected in series. The return cable 46 electrically connects the safety switch 30 at the next to the last tower 12N to the second port of the safety signal source 42. In some embodiments, the switch cable 44 and the return cable 46 each extend to the last tower 12N+1. The safety switches 30, the switch cable 44, and the return cable 46 form an electrically conductive closed circuit path when all of the safety switches 30 are closed, which may be known as a “normal state”.

The irrigation system 10 further includes a relay 47 that is utilized to electrically isolate the differential voltage measurement circuit 32 from the safety signal source 42. The relay 47 includes a common contact that is electrically connected to the switch cable 44 between the central controller 14 and the safety switch 30 of the first tower 12A. The relay 47 further includes a normally closed (NC) contact that is electrically connected to one port of the safety signal source 42, and a normally open (NO) contact that is electrically connected to the differential voltage measurement circuit 32. In the non-energized state of the relay 47, the switch cable 44 is electrically connected to the safety signal source 42. In the energized state of the relay 47, the switch cable 44 is electrically connected to the differential voltage measurement circuit 32. The state of the relay 47, i.e., non-energized or energized, is determined by the processor 40 through one or more control lines.

Referring to FIG. 2, the safety switches 30 and the switch cable 44 in combination with an impedance cable 48 form the safety switch circuit 34. The impedance cable 48 is an electrically conductive cable that is electrically connected to the differential voltage measurement circuit 32 and extends from the central controller 14 (typically located at the center pivot 16) to the next to the last tower 12N and positioned in general proximity to the switch cable 44. In some embodiments, the impedance cable 48 along with the switch cable 44 and the return cable 46 each extend to the last tower 12N+1. The impedance cable 48 may be utilized for other control purposes when the irrigation machine is running, such as FWD, REV, % SPEED, End Gun1 and End Gun2 commands.

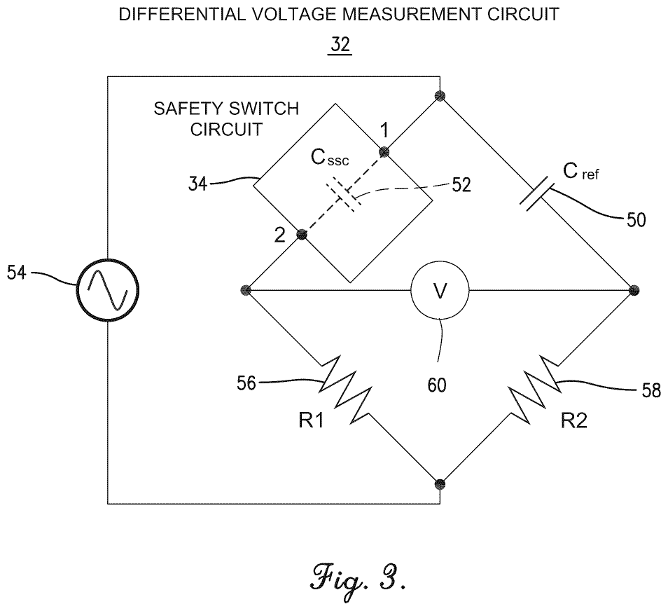

The differential voltage measurement circuit 32 measures a differential voltage resulting from a difference in capacitance between a reference capacitor 50 and a safety switch circuit capacitor 52, wherein the difference varies according to a location, or position, of an open safety switch 30, or a distance from a reference point to the open safety switch 30. The reference point is typically the point at which the differential voltage is measured. The differential voltage measurement circuit 32 includes a voltage source 54, a first resistor 56, a second resistor 58, the safety switch circuit capacitor 52, and the reference capacitor 50, as shown in FIG. 3. The voltage source 54 is a varying voltage source, such as an alternating current (AC) voltage source formed from known electric power supplies which output sine wave voltage with a selectively specified frequency and amplitude or a direct current (DC) square wave voltage source with a selectively specified frequency and amplitude. Exemplary embodiments of the voltage source 54 output AC voltage with a value greater than 12 VAC and an oscillating frequency that ranges between approximately 60 Hertz (Hz) and approximately 400 Hz, wherein approximately 240 Hz is optimal.

The first resistor 56 and the second resistor 58 typically have the same selectively specified resistance value. The reference capacitor 50, which forms a reference load, has a selectively specified capacitance value. In certain embodiments, the capacitance value of the reference capacitor 50 may be fixed. The safety switch circuit capacitor 52 is a virtual capacitor formed by the safety switch circuit 34, that is, the switch cable 44, the safety switches 30, and the impedance cable 48, which in combination also forms a safety switch circuit load. In other words, in the differential voltage measurement circuit 32, the safety switch circuit 34 is modeled as the safety switch circuit capacitor 52. Its capacitance value varies according to, or is determined by, the position, or ordinal number, of the tower 12 having the open safety switch 30, wherein, generally, a higher ordinal number results in a greater capacitance and vice-versa. (The capacitance value of the safety switch circuit capacitor 52 is a maximum when all safety switches 30 are closed.) For example, if the irrigation system 10 includes ten (10) towers 12 and associated safety switches 30, the capacitance value of the safety switch circuit capacitor 52 is greater when the ninth safety switch 30 is open compared to the second safety switch 30 being open. In addition, the capacitance value of the safety switch circuit capacitor 52 varies according to the distance from the reference, or measurement, point to the open safety switch 30, wherein, generally, a greater distance results in a greater capacitance and vice-versa.

Referring to FIG. 3, the safety switch circuit capacitor 52 and the reference capacitor 50 are each electrically connected to a first terminal of the voltage source 54. The safety switch circuit capacitor 52 is also electrically connected to the first resistor 56, and the reference capacitor 50 is also electrically connected to the second resistor 58. The first resistor 56 and the second resistor 58 are each also electrically connected to a second terminal of the voltage source 54. The differential voltage measurement circuit 32 further includes a voltmeter 60, or voltage sensing circuitry, that measures the voltage from the connection between the safety switch circuit capacitor 52 and the first resistor 56 to the connection between the reference capacitor 50 and the second resistor 58. The voltmeter 60, being connected in this fashion, is configured to measure a difference in voltage drop across the reference capacitor 50 and the safety switch circuit capacitor 52. In addition, the differential voltage measurement circuit 32 includes first and second ports, with reference numerals 1 and 2, respectively, that electrically connect to the safety switch circuit 34, wherein the first port 1 is electrically connected to the impedance cable 48 and the second port 2 is electrically connected to the normally open contact of the relay 47, as shown in FIG. 2. The first port 1 and the second port 2 are also shown in FIG. 3, wherein the first port 1 is a first terminal of the safety switch circuit capacitor 52 (formed by the safety switch circuit 34) and the second port 2 is a second terminal of the safety switch circuit capacitor 52.

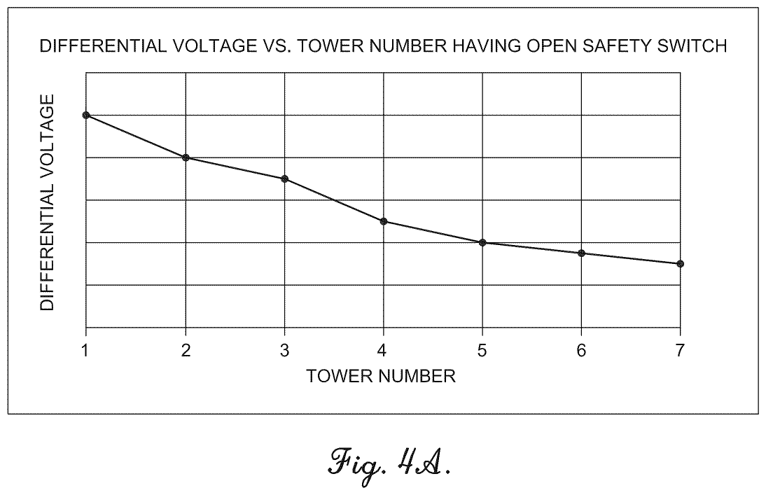

The differential voltage measurement circuit 32 operates as follows. The reference capacitor 50, the safety switch circuit capacitor 52, the first resistor 56, and the second resistor 58 are connected to one another to form a symmetrical bridge circuit. When the resistance of the first resistor 56 and the second resistor 58 are equivalent, which they are typically selected to be, and the capacitance of the reference capacitor 50 and the safety switch circuit capacitor 52 are equivalent, the load portion of the circuit is balanced. (The capacitance value of the reference capacitor 50 may be adjusted in situ in order to be equal to the capacitance of the safety switch circuit capacitor 52.) Alternatively, the capacitance value of the reference capacitor 50 may be fixed, but selected to meet various design criteria. The voltage source 54 outputs sinusoidal AC voltage or DC square wave voltage, and, given that the load is balanced, the voltage drop across the two capacitors is the same. Thus, the voltmeter 60 measures approximately zero Volts. When one of the safety switches 30 opens, the capacitance of the safety switch circuit capacitor 52 decreases to a value which varies according to the position, or location, of the tower 12 having the open safety switch 30 or the distance from the reference, or measurement, point to the open safety switch 30. The change in capacitance of the safety switch circuit capacitor 52 results in a difference in voltage drop across the two capacitors. The difference in voltage drop across the two capacitors, i.e., the differential voltage, is measured by the voltmeter 60. The value of the differential voltage varies according to the difference in capacitance between the two capacitors. Since the capacitance of the safety switch circuit capacitor 52 varies according to the numeric position of the tower 12 having the open safety switch 30, the value of the differential voltage also varies according to the numeric position of the tower 12 having the open safety switch 30. A first example of how the differential voltage varies according to the numeric position of the tower 12 having the open safety switch 30 is shown in the plot of FIG. 4A. The plot illustrates the differential voltage vs. the tower number for an irrigation system 10 that includes at least seven (7) towers 12 having one of the safety switches 30. As can be seen, for a first combination of circuit values, the voltage decreases somewhat non-linearly according to the tower number. A second example of how the differential voltage varies according to the numeric position of the tower 12 having the open safety switch 30 is shown in the plot of FIG. 4B. For a second combination of circuit values, the voltage increases somewhat non-linearly according to the tower number.

Alternatively, the differential voltage measurement circuit 32 may operate with the reference capacitor 50 not being equal in capacitance to the safety switch circuit capacitor 52 by default. This results in the measured differential voltage being nonzero, or having an offset, by default. The operation of the differential voltage measurement circuit 32 may be substantially the same as described in the previous paragraph except that the measured differential voltage automatically includes the offset.

The differential voltage measurement circuit 32 outputs the differential voltage signal (received by the processor 40) which includes a voltage or data value that varies according to the measured differential voltage. In some embodiments, the differential voltage measurement circuit 32 may include a processor itself, similar to the processor 40, which determines the identification of the tower 12 having the open safety switch 30 according to the measured differential voltage. The processor may determine the position including the identification of, and/or the distance to, the tower 12 with the open safety switch 30 by solving a mathematical equation that calculates the identification and/or distance as a function of the measured differential voltage. Additionally, or alternatively, the processor may determine the identification of, and/or the distance to, the tower 12 with the open safety switch 30 by querying a lookup table. The lookup table may include a listing of tower identifications, wherein each tower identification is associated with a range of values, of the voltage or data, of the measured differential voltage. The differential voltage measurement circuit 32 outputs the differential voltage signal which includes a voltage or data value that varies according to the identification of, and/or the distance to, the tower 12 having the open safety switch 30.

The irrigation system 10 may operate as follows. The irrigation system 10 may be operating under normal parameters. That is, the drive motors 26 may be moving each tower 12 independently, perhaps at different speeds and at different times, such that the successive sections of the conduit 20 are rotating with respect to one another and the alignment angles between adjacent sections are within the safety threshold values. For one of any number of reasons, such as the tires getting stuck in a rut, a high wind event, or the like, one of the towers 12 may experience a problem that results in the alignment angle between the two sections of conduit 20 joined at the tower 12 exceeding the safety threshold value. The safety signal source 42 detects that the safety signal is no longer being received and alerts the processor 40. After a period of time, the processor 40 shuts down the operation of the irrigation system 10. The processor 40 also energizes the relay 47 to connect the differential voltage measurement circuit 32 to the switch cable 44 and instructs the differential voltage measurement circuit 32 to operate. The voltage source 54 outputs sinusoidal AC voltage or DC square wave voltage and the voltmeter 60 measures the differential voltage. The differential voltage measurement circuit 32 outputs the differential voltage signal, which is received by the processor 40. Depending on the content of the differential voltage signal, the processor 40 either determines the identification of, and/or or the distance to, the tower 12 having the open safety switch 30 or receives the identification and/or or the distance. The processor 40 may further output a message indicating the tower 12, the location of the tower 12, or a distance to the tower 12 which has the open safety switch 30. Thus, the technician arriving to repair the irrigation system 10 knows which tower 12 to check. In addition, or instead, the message may be displayed on a display at the center pivot 16.

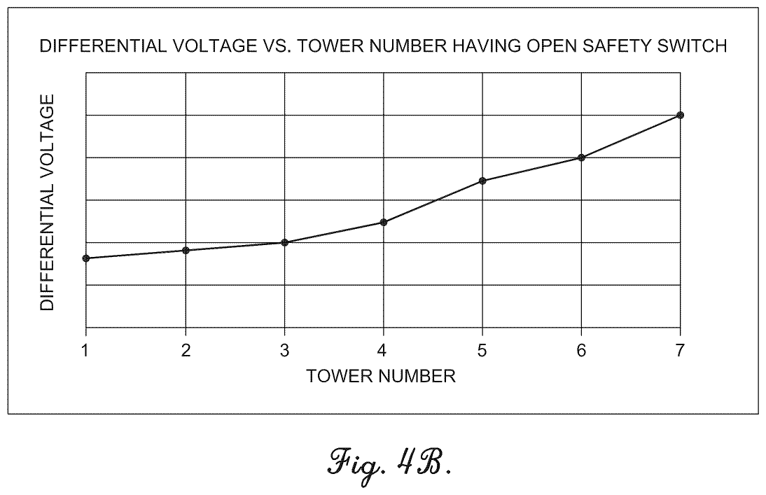

Referring to FIG. 5, a second embodiment of the differential voltage measurement circuit 132 is shown. The differential voltage measurement circuit 132 is similar in function and purpose to the differential voltage measurement circuit 32 in that the differential voltage measurement circuit 132 measures a differential voltage resulting from a difference in electrical characteristics between reference electrical components and the safety switch circuit 34. The differential voltage measurement circuit 132 is different from the differential voltage measurement circuit 32 in that the differential voltage measurement circuit 132 provides a different model of the safety switch circuit 34, which in turn, requires an additional reference component.

The differential voltage measurement circuit 132 includes a reference capacitor 150, a safety switch circuit capacitor 152, a voltage source 154, a first resistor 156, a second resistor 158, a voltmeter 160, a safety switch circuit resistor 162, and a reference resistor 164. The reference capacitor 150, the safety switch circuit capacitor 152, the voltage source 154, the first resistor 156, the second resistor 158, and the voltmeter 160 are each similar to, or the same as, the like-named components described above for the differential voltage measurement circuit 32. The safety switch circuit resistor 162 is a virtual resistor formed by the safety switch circuit 34, that is, the switch cable 44, the safety switches 30, and the impedance cable 48. In the differential voltage measurement circuit 132, the safety switch circuit 34 is modeled as the safety switch circuit capacitor 152 in combination with the safety switch circuit resistor 162. An impedance value of the capacitor and resistor combination 152, 162 varies according to, or is determined by, the position, or ordinal number, of the tower 12 having the open safety switch 30 or a distance from a reference, or measurement, point to the open safety switch 30, wherein, generally a higher ordinal number or greater distance results in a greater impedance and vice-versa. (The impedance value of the capacitor and resistor combination 152, 162 is a maximum when all safety switches 30 are closed.) For example, if the irrigation system 10 includes eleven (11) towers 12 and ten (10) safety switches 30, the impedance value of the capacitor and resistor combination 152, 162 is greater when the ninth safety switch 30 is open compared to the second safety switch 30 being open. The reference resistor 164 has a selectively specified resistance value. In various embodiments, the reference capacitor 150 may have a fixed capacitance value, and the reference resistor 164 may have a fixed resistance value, with each value being selected to meet design criteria. In addition, the impedance value of the capacitor and resistor combination 152, 162 varies according to the distance from the reference, or measurement, point to the open safety switch 30, wherein, generally, a greater distance results in a greater impedance and vice-versa.

The configuration or topology of the differential voltage measurement circuit 132 is similar to that of the differential voltage measurement circuit 32, except that the safety switch circuit resistor 162 is (virtually) connected in series with the safety switch circuit capacitor 152, and the reference resistor 164 is electrically connected in parallel with the reference capacitor 150. The voltmeter 160 measures the voltage from the connection between the safety switch circuit resistor 162 and the first resistor 156 to the connection between the parallel combination of the reference capacitor 150 with the reference resistor 164 and the second resistor 158. Expressed another way, the voltmeter 160 measures the difference in voltage drop between a safety switch circuit load (i.e., the series combination of the safety switch circuit resistor 162 and the safety switch circuit capacitor 152, which is formed by the safety switch circuit 34) and a reference load (i.e., the parallel combination of the reference resistor 164 and the reference capacitor 150.)

The differential voltage measurement circuit 132 operates as follows. The voltage source 154 outputs sinusoidal AC voltage or DC square wave voltage. The capacitance value of the reference capacitor 150 and the resistance value of the reference resistor 164 may be adjusted in situ in order to be equal to the capacitance of the safety switch circuit capacitor 152 and the resistance of the safety switch circuit resistor 162, respectively. This adjustment ensures that the differential voltage, measured by the voltmeter 160, is approximately zero Volts when all of the safety switches 30 are closed. Alternatively, the capacitance value of the reference capacitor 150 and the resistance value of the reference resistor 164 may be fixed, but selected to meet various design criteria. When one of the safety switches 30 opens, the values of both the safety switch circuit capacitor 152 and the safety switch circuit resistor 162 change, which leads to a change in the measured differential voltage. The differential voltage varies according to the numeric position of, a location of, or a distance from a reference, or measurement, point to, the tower 12 having the open safety switch 30. The differential voltage for the differential voltage measurement circuit 132 may vary in a similar fashion to the differential voltage measurement circuit 32 such as the example shown in FIGS. 4A and 4B and described above.

Like with the differential voltage measurement circuit 32, the differential voltage measurement circuit 132 may alternatively operate with the values of the reference load not being equal to the values the safety switch circuit load by default. This results in the measured differential voltage being nonzero, or having an offset, by default. The operation of the differential voltage measurement circuit 132 may be substantially the same as described in the previous paragraph except that the measured differential voltage automatically includes the offset.

The differential voltage measurement circuit 132 outputs the differential voltage signal (received by the processor 40) which includes a voltage or data value that varies according to the measured differential voltage in the same fashion as described above for the differential voltage measurement circuit 32.

The irrigation system 10 with the differential voltage measurement circuit 132 operates in the same fashion as the differential voltage measurement circuit 32. That is, when one of the safety switches 30 opens and the processor 40 shuts down the operation of the irrigation system 10, the processor 40 also instructs the differential voltage measurement circuit 132 to operate. The voltage source 154 outputs sinusoidal AC voltage or DC square wave voltage and the voltmeter 160 measures the differential voltage. The differential voltage measurement circuit 132 outputs the differential voltage signal, which is received by the processor 40. Depending on the content of the differential voltage signal, the processor 40 either determines the identification of, and/or the distance to, the tower 12 having the open safety switch 30 or receives the identification and/or the distance. The processor 40 may further output a message indicating the tower 12, the location of the tower 12, or a distance to the tower 12 which has the open safety switch 30. Thus, the technician arriving to repair the irrigation system 10 knows which tower 12 to check. In addition, or instead, the message may be displayed on a display at the center pivot 16.

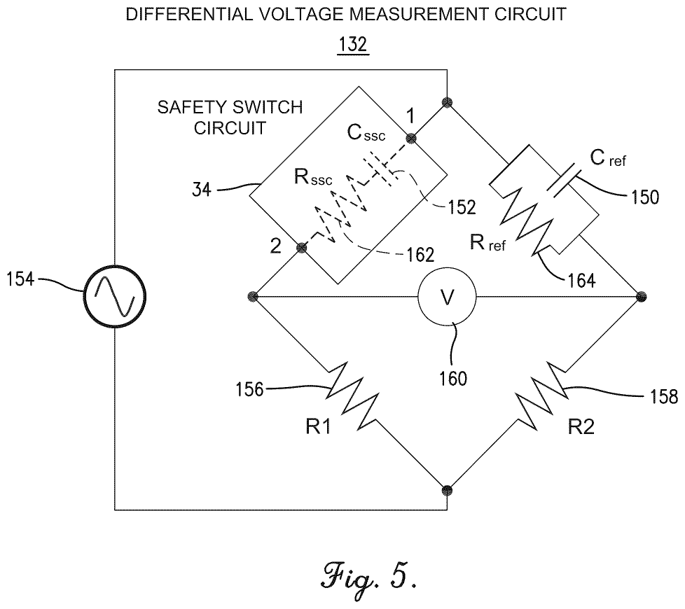

Referring to FIG. 6, a third embodiment of the differential voltage measurement circuit 232 is shown. The differential voltage measurement circuit 232 is similar in function and purpose to the differential voltage measurement circuit 32 and the differential voltage measurement circuit 132 in that the differential voltage measurement circuit 232 measures a differential voltage resulting from a difference in electrical characteristics between reference electrical components and the safety switch circuit 34. The differential voltage measurement circuit 232 is different from the differential voltage measurement circuit 32, 132 in that the differential voltage measurement circuit 232 provides a different model of the safety switch circuit 34 by utilizing different components.

The differential voltage measurement circuit 132 includes a reference inductor 250, a safety switch circuit inductor 252, a voltage source 254, a first resistor 256, a second resistor 258, and a voltmeter 260. The voltage source 254, the first resistor 256, the second resistor 258, and the voltmeter 260 are each similar to, or the same as, the like-named components described above for the differential voltage measurement circuit 32, 132. The reference inductor 250, which forms a reference load, has a selectively specified inductance value. In certain embodiments, the inductance value of the reference inductor 250 may be fixed. The safety switch circuit inductor 252 is a virtual inductor or safety switch circuit load formed by the safety switch circuit 34, that is, the switch cable 44, the safety switches 30, and the impedance cable 48. In other words, the safety switch circuit 34 is modeled as the safety switch circuit inductor 252. Its inductance value varies according to, or is determined by, the position or ordinal number of, or a distance from a reference, or measurement, point to, the tower 12 having the open safety switch 30, wherein generally a higher ordinal number results in a greater inductance and vice-versa. (The inductance value of the safety switch circuit inductor 252 is a maximum when all safety switches 30 are closed.) For example, if the irrigation system 10 includes ten (10) towers 12 and associated safety switches 30, the inductance value of the safety switch circuit inductor 252 is greater when the ninth safety switch 30 is open compared to the second safety switch 30 being open.

The configuration or topology of the differential voltage measurement circuit 232 is similar to that of the differential voltage measurement circuit 32, except that the reference inductor 250 is connected in place of the reference capacitor 50, and the safety switch circuit inductor 252 is connected in place of the safety switch circuit capacitor 52.

The differential voltage measurement circuit 232 operates as follows. The voltage source 254 outputs sinusoidal AC voltage or DC square wave voltage. The inductance value of the reference inductor 250 may be adjusted in situ in order to be equal to the inductance of the safety switch circuit inductor 252. This adjustment ensures that the differential voltage, measured by the voltmeter 260, is approximately zero Volts when all of the safety switches 30 are closed. Alternatively, the inductance value of the reference inductor 250 may be fixed, but selected to meet various design criteria. When one of the safety switches 30 opens, the value of the safety switch circuit inductor 252 changes, which leads to a change in the measured differential voltage. The differential voltage varies according to the numeric position or ordinal number of, or the distance from a reference, or measurement, point to, the tower 12 having the open safety switch 30. The differential voltage for the differential voltage measurement circuit 232 may vary in a similar fashion to the differential voltage measurement circuit 32 such as the example shown in FIGS. 4A and 4B and described above.

Like with the differential voltage measurement circuit 32, the differential voltage measurement circuit 232 may alternatively operate with the values of the reference load not being equal to the values the safety switch circuit load by default. This results in the measured differential voltage being nonzero, or having an offset, by default. The operation of the differential voltage measurement circuit 232 may be substantially the same as described in the previous paragraph except that the measured differential voltage automatically includes the offset.

The irrigation system 10 with the differential voltage measurement circuit 232 operates in the same fashion as the differential voltage measurement circuit 32. That is, when one of the safety switches 30 opens and the processor 40 shuts down the operation of the irrigation system 10, the processor 40 also instructs the differential voltage measurement circuit 232 to operate. The voltage source 254 outputs sinusoidal AC voltage or DC square wave voltage and the voltmeter 260 measures the differential voltage. The differential voltage measurement circuit 232 outputs the differential voltage signal, which is received by the processor 40. Depending on the content of the differential voltage signal, the processor 40 either determines the identification of, and/or the distance to, the tower 12 having the open safety switch 30 or receives the identification and/or the distance. The processor 40 may further output a message indicating the tower 12, the location of the tower 12, or a distance to the tower 12 which has the open safety switch 30. Thus, the technician arriving to repair the irrigation system 10 knows which tower 12 to check. In addition, or instead, the message may be displayed on a display at the center pivot 16.

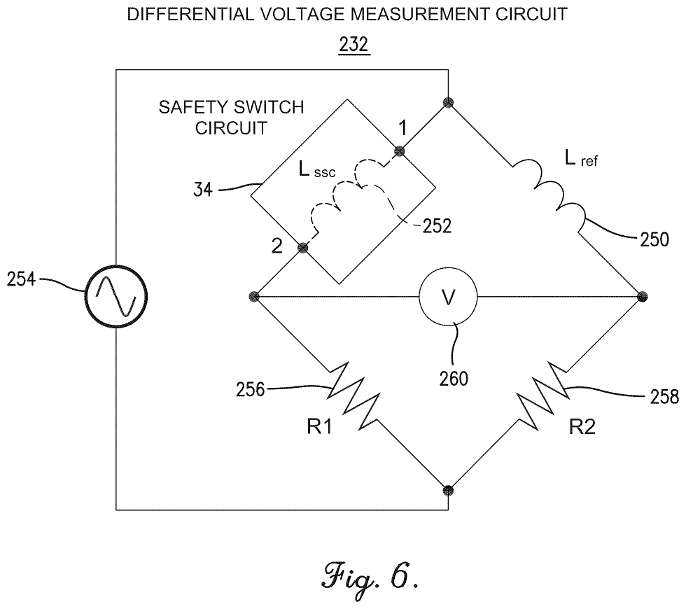

FIG. 7 depicts a listing of at least a portion of the steps of an exemplary method 300 for identifying an open safety switch 30 in an irrigation system 10, which may include a distance from a differential voltage measurement circuit 32, 132, 232 to the open safety switch 30, a location of the open safety switch 30, and/or an identifier, such as an ordinal number, of a tower 12 associated with the open safety switch 30. Variations to the steps may be performed. The steps may be performed in the order shown in FIG. 7, or they may be performed in a different order. Furthermore, some steps may be performed concurrently as opposed to sequentially. In addition, some steps may be optional or may not be performed.

Referring to step 301, an impedance cable 48 is positioned in proximity to a safety switch cable 44 that electrically connects a plurality of safety switches 30 to one another to form a safety switch circuit 34. The irrigation system 10 includes at least a plurality of spaced-apart, motorized, and self-propelled towers 12 which support a fluid-carrying conduit 20 and sprayer system that sprays the fluid on one or more crops. Between each adjacent pair of towers 12 is a successive one of a plurality of sections of the conduit 20, wherein each adjacent pair of conduit sections is coupled with a successive one of a plurality of joints that is flexible.

Each safety switch 30 is embodied by a single-pole, single-throw (SPST) type switch, or any type of switch that includes a first terminal and a second terminal with a moveable contact providing electrical connection between the terminals in a closed position and no electrical connection in an open position. The safety switch 30 is closed when the alignment angle between the two sections of the conduit 20 joined at the associated tower 12 is below or equal to a safety threshold value and open when alignment angle is above the safety threshold value. The safety switch 30 may be implemented as a limit switch that is integrated in a mechanical assembly which includes a rotating cam mechanically coupled to the conduit 20 at the joint where two sections of the conduit 20 are connected. The cam rotates in response to the rotation of the outward section of the conduit 20 with respect to the inward section of the conduit 20, and thus the angular position of the cam represents the alignment angle between the two sections of the conduit 20. Rotation of the cam beyond the safety threshold angle, in either the clockwise direction or the counter clockwise direction, opens the safety switch 30.

Each of the safety switches 30 is electrically connected to the safety signal source 42 through the switch cable 44 and a return cable 46, as shown in FIG. 2. The switch cable 44 includes a plurality of sections, wherein a first section electrically connects the first port of the safety signal source 42 to the safety switch 30 at the first tower 12A. A successive one of other sections of the switch cable 44 electrically connects each successive adjacent pair of safety switches 30 to one another so that all of the safety switches 30 are electrically connected in series.

The return cable 46 electrically connects the safety switch 30 at the next to the last tower 12N to the second port of the safety signal source 42. In some embodiments, the switch cable 44 and the return cable 46 each extend to the last tower 12N+1. The safety switches 30, the switch cable 44, and the return cable 46 form an electrically conductive closed circuit path when all of the safety switches 30 are closed, which may be known as a “normal state”.

Referring to FIG. 2, the safety switches 30 and the switch cable 44 in combination with the impedance cable 48 form the safety switch circuit 34. The impedance cable 48 is an electrically conductive cable that extends from the central controller 14 (typically located at the center pivot 16) to the next to the last tower 12N and positioned in general proximity to the switch cable 44. In some embodiments, the impedance cable 48 along with the switch cable 44 and the return cable 46 each extend to the last tower 12N+1. The impedance cable 48 may be utilized for other control purposes when the irrigation machine is running, such as FWD, REV, % SPEED, End Gun1 and End Gun2 commands.

Referring to step 302, an alternating current (AC) voltage is applied to the safety switch circuit 34 and a reference load. The AC voltage is output by a voltage source 54, 154, 254, which is a component of a differential voltage measurement circuit 32, 132, 232. Referring to FIGS. 3 and 5, the differential voltage measurement circuit 32, 132 includes the voltage source 54, 154, a first resistor 56, 156, a second resistor 58, 158, a reference capacitor 50, 150, and a safety switch circuit capacitor 52, 152. Various embodiments of the differential voltage measurement circuit 132 also include a safety switch circuit resistor 162 and a reference resistor 164, as shown in FIG. 5. Referring to FIG. 6, the differential voltage measurement circuit 232 includes the voltage source 254, a first resistor 256, a second resistor 258, a reference inductor 250, and a safety switch circuit inductor 252.

The voltage source 54, 154 is a varying voltage source, such as an alternating current (AC) voltage source formed from known electric power supplies which output sine wave voltage with a selectively specified frequency and amplitude or a direct current (DC) square wave voltage source with a selectively specified frequency and amplitude. Exemplary embodiments of the voltage source 54, 154 output AC voltage with a value greater than 12 VAC and an oscillating frequency that ranges between approximately 60 Hertz (Hz) and approximately 400 Hz, wherein 240 Hz is optimal. The first resistor 56, 156 and the second resistor 58, 158 typically have the same selectively specified resistance value. The reference capacitor 50, 150, which forms the reference load, has a selectively specified capacitance value. In some embodiments, the reference capacitor 50, 150 has a fixed capacitance value. The safety switch circuit capacitor 52, 152 is a virtual capacitor formed by the safety switch circuit 34, that is, the switch cable 44, the safety switches 30, and the impedance cable 48, which in combination also forms a safety switch circuit load. Its capacitance value varies according to, or is determined by, the position or ordinal number of, or a distance from a reference, or measurement, point to, the tower 12 having the open safety switch 30, wherein, generally a higher ordinal number results in a greater capacitance and vice-versa. (The capacitance value of the safety switch circuit capacitor 52, 152 is a maximum when all safety switches 30 are closed.) For example, if the irrigation system 10 includes eleven (11) towers 12 and ten (10) safety switches 30, the capacitance value of the safety switch circuit capacitor 52, 152 is greater when the ninth safety switch 30 is open compared to the second safety switch 30 being open.

The safety switch circuit resistor 162 is a virtual resistor formed by the safety switch circuit 34, that is, the switch cable 44, the safety switches 30, and the impedance cable 48. An impedance value of the capacitor and resistor combination 152, 162 varies according to, or is determined by, the position or ordinal number of, or the distance from a reference, or measurement, point to, the tower 12 having the open safety switch 30, wherein, generally a higher ordinal number results in a greater impedance and vice-versa. (The impedance value of the capacitor and resistor combination 152, 162 is a maximum when all safety switches 30 are closed.) For example, if the irrigation system 10 includes ten (10) towers 12 and associated safety switches 30, the impedance value of the capacitor and resistor combination 152, 162 is greater when the ninth safety switch 30 is open compared to the second safety switch 30 being open. The reference resistor 164 has a selectively specified resistance value. In various embodiments, the reference load includes the reference capacitor 50, 150 and the reference resistor 164.

In the differential voltage measurement circuit 232, the voltage source 254 is a varying voltage source, such as an alternating current (AC) voltage source formed from known electric power supplies which output sine wave voltage with a selectively specified frequency and amplitude or a direct current (DC) square wave voltage source with a selectively specified frequency and amplitude. Exemplary embodiments of the voltage source 254 output AC voltage with a value greater than 12 VAC and an oscillating frequency that ranges between approximately 60 Hertz (Hz) and approximately 400 Hz, wherein 240 Hz is optimal. The first resistor 256 and the second resistor 258 typically have the same selectively specified resistance value. The reference inductor 250, which forms the reference load, has a selectively specified inductance value. In some embodiments, the reference inductor 250 has a fixed inductance value. The safety switch circuit inductor 252 is a virtual inductor formed by the safety switch circuit 34, that is, the switch cable 44, the safety switches 30, and the impedance cable 48. In other words, the safety switch circuit 34 is modeled as the safety switch circuit inductor 252. Its inductance value varies according to, or is determined by, the position or ordinal number of, or the distance from a reference, or measurement, point to, the tower 12 having the open safety switch 30, wherein generally a higher ordinal number results in a greater inductance and vice-versa. (The inductance value of the safety switch circuit inductor 252 is a maximum when all safety switches 30 are closed.) For example, if the irrigation system 10 includes eleven (11) towers 12 and ten (10) safety switches 30, the inductance value of the safety switch circuit inductor 252 is greater when the ninth safety switch 30 is open compared to the second safety switch 30 being open.

In the differential voltage measurement circuit 32, the safety switch circuit 34 is modeled as the safety switch circuit capacitor 52. In the differential voltage measurement circuit 132, the safety switch circuit 34 is modeled as the safety switch circuit capacitor 152 in combination with the safety switch circuit resistor 162. In the differential voltage measurement circuit 232, the safety switch circuit 34 is modeled as the safety switch circuit inductor 252.

Referring to step 303, a differential voltage between a voltage drop across the safety switch circuit 34 and a voltage drop across the reference load is measured. The differential voltage measurement circuit 32, 132, 232 further includes a voltmeter 60, 160, 260, or voltage sensing circuitry, which measures the voltage from the connection between the safety switch circuit 34 and the first resistor 56, 156, 256 to the connection between the reference load and the second resistor 58, 158, 258. The voltmeter 60, 160, 260, being connected in this fashion, is configured to measure a difference in voltage drop across the reference load and the safety switch circuit 34.

Referring to step 304, a position of an open safety switch 30 is determined according to the differential voltage. The differential voltage measurement circuit 32, 132, 232 outputs the differential voltage signal (received by a processor 40) which includes a voltage or data value that varies according to the measured differential voltage. The processor 40 receives the differential voltage signal and determines a position, including an identification, such as a numerical value representing the order, of the tower 12 with the open safety switch 30 and/or a distance from the center pivot 16 to the tower 12 with the open safety switch 30. The processor 40 may determine the identification of, and/or the distance to, the tower 12 with the open safety switch 30 by solving a mathematical equation that calculates the identification and/or distance as a function of the content of the differential voltage signal. Additionally, or alternatively, the processor 40 may determine the identification of, and/or the distance to, the tower 12 with the open safety switch 30 by querying a lookup table. The lookup table may include a listing of tower identifications, wherein each tower identification is associated with a range of values, of the voltage or data, of the differential voltage signal. Or, the lookup table may include a listing of a plurality of distances outward from the center pivot 16. The distances may include a distance from the center pivot 16 to each tower 12. Or the distances may include a plurality of intermediate distances as well. Each distance is associated with a range of values, of the voltage or data, of the differential voltage signal. Additionally, or alternatively, the processor 40 may determine a location (or geolocation) of the open safety switch 30 which varies according to the value, of the voltage or data, of the differential voltage signal.

In some embodiments, the differential voltage measurement circuit 32, 132, 232 may include a processor itself, similar to the processor 40, which determines the identification of the tower 12 having the open safety switch 30 according to the measured differential voltage. The processor may determine the identification of, and/or the distance to, the tower 12 with the open safety switch 30 by solving a mathematical equation that calculates the identification and/or distance as a function of the measured differential voltage. Additionally, or alternatively, the processor may determine the identification of, and/or the distance to, the tower 12 with the open safety switch 30 by querying a lookup table. The lookup table may include a listing of tower identifications, wherein each tower identification is associated with a range of values, of the voltage or data, of the measured differential voltage. The differential voltage measurement circuit 32 outputs the differential voltage signal which includes a voltage or data value that varies according to the identification, or location, of, or the distance to, the tower 12 having the open safety switch 30.

The processor 40 may in addition output a message, that is transmitted through the communication element 36, indicating that one of the safety switches 30 has opened and the irrigation system 10 has shut down. The message may also indicate the number of, identification of, location of, or distance to, the tower 12 with the open safety switch 30. The message may be received by an external receiver, such as an operations center, an owner of the property, a technician who maintains the irrigation system 10, or combinations thereof. Alternatively, or additionally, the central controller 14 may include a display at the center pivot which displays the message.

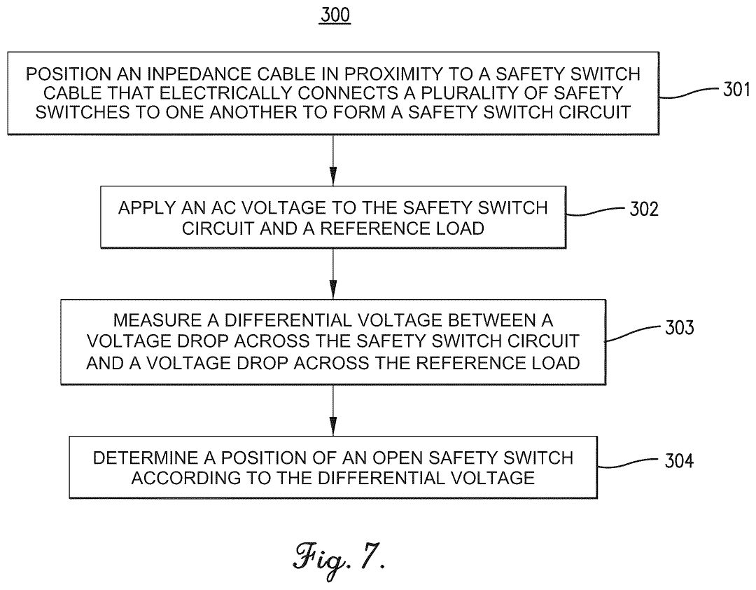

In the embodiments of the differential voltage measurement circuit 32, 132, 232 described above, when one of the safety switches 30 opens, the impedance of the safety switch circuit 34 changes (due to changes in the resistance, capacitance, and/or inductance of the components of the safety switch circuit 34) which creates an imbalance between the reference load and the load of the safety switch circuit 34, resulting in a non-zero differential voltage measured by the voltmeter 60, 160, 260. The processor 40 then determines a distance to, or a position of, the tower 12 that has the open safety switch 30 according to, or based on, the value of the differential voltage. Referring to FIGS. 8, 9, and 10, in other embodiments of the differential voltage measurement circuit 32-A, 132-A, 232-A, the central controller 14 is configured to adjust the electrical characteristics of the reference load, including a reference capacitor 50-A, a reference capacitor 150-A and a reference resistor 162-A, and a plurality of reference inductors 250-1-250-n, when an open safety switch 30 is detected such that the differential voltage measured by the voltmeter 60, 160, 260 of the differential voltage measurement circuit 32, 132, 232 is zero Volts. The processor 40 then determines a distance to, or a position of, the tower 12 that has the open safety switch 30 according to, or based on, an amount of adjustment that is required to bring the differential voltage back to zero Volts.

Referring to FIG. 8, the differential voltage measurement circuit 32-A includes the reference capacitor 50-A which has a variable capacitance value. In some embodiments, the reference capacitor 50-A may include a plurality of physical capacitors with variable capacitance. The capacitance value of the reference capacitor 50-A is controlled electronically or tuned digitally by the processor 40 through one or more control signals.

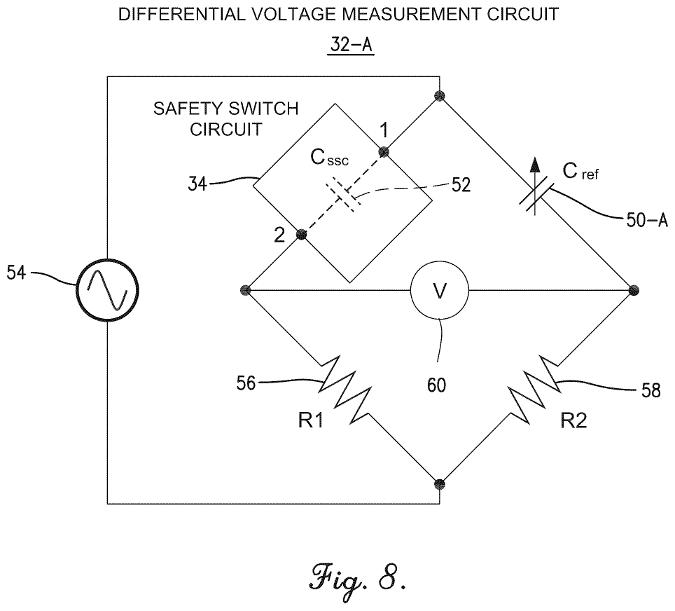

Referring to FIG. 9, the differential voltage measurement circuit 132-A includes the reference capacitor 150-A which has a variable capacitance value and the reference resistor 164-A which has a variable resistance value. In some embodiments, the reference capacitor 150-A may include a plurality of physical capacitors with variable capacitance and the reference resistor 164-A may include a plurality of physical resistors with variable resistance. The capacitance value of the reference capacitor 150-A and the resistance value of the reference resistor 164-A are each controlled electronically or tuned digitally by the processor 40 through one or more control signals.

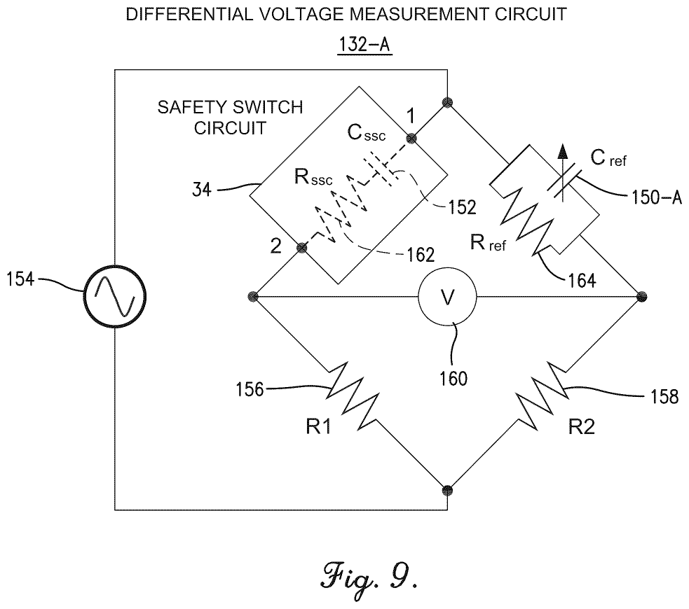

Referring to FIG. 10, the differential voltage measurement circuit 232-A includes the reference inductors 250-1-250-n as well as a plurality of switches 266-1-266-n. Each reference inductor 250 has a unique inductance value, wherein the inductance value may be roughly equal to the inductance value of the safety switch circuit inductor 252 when each successive safety switch 30 is open. For example, the reference inductor 250-1 may have an inductance value roughly equal to the inductance value of the safety switch circuit inductor 252 when the (first) safety switch 30 at the first tower 12A is open. The reference inductor 250-2 may have an inductance value roughly equal to the inductance value of the safety switch circuit inductor 252 when the (second) safety switch 30 at the second tower 12B is open and so forth.

Alternatively, each reference inductor 250 may have an inductance value that is selected in order to provide a range of different inductance values. Each switch 266 is an SPST or toggle type electrical switch having an open state or a closed state, wherein the state is electronically controlled by the processor 40 through one or more control signals. Each switch 266 is electrically connected in series with a successive one of the inductors 250. And, each switch 266 and inductor 250 combination is electrically connected in parallel with the other switch 266 and inductor 250 combinations.

The irrigation system 10, with the differential voltage measurement circuit 32-A, 132-A, and 232-A, may operate as follows. When one of the safety switches 30 opens, the safety signal source 42 detects that the safety signal is no longer being received and alerts the processor 40. After a period of time, the processor 40 shuts down the operation of the irrigation system 10. The processor 40 also energizes the relay 47 to connect the differential voltage measurement circuit 32-A, 132-A, 232-A to the switch cable 44 and instructs the differential voltage measurement circuit 32-A, 132-A, 232-A to operate. The voltage source 54, 154, 254 outputs sinusoidal AC voltage or DC square wave voltage and the voltmeter 60, 160, 260 measures the differential voltage. The differential voltage measurement circuit 32-A, 132-A, 232-A outputs the differential voltage signal, which is received by the processor 40.

For the differential voltage measurement circuit 32-A, 132-A, the processor 40 may utilize a search-type algorithm to increase or decrease the capacitance value or the capacitance and resistance values of the reference capacitor 50 and the reference capacitor 150 and reference resistor 164, respectively, until the differential voltage measurement from the voltmeter 60, 160, 260 is approximately zero Volts. The processor 40 also records the amount by which the capacitance value or the capacitance and resistance values of the reference capacitor 50 and the reference capacitor 150 and reference resistor 164, respectively, is/are changed. The processor 40 may use the amount of change as an input to one or more mathematical equations or a lookup table to determine a distance from a reference point to, a location of, or an identity of, the tower 12 whose safety switch 30 is open.

For the differential voltage measurement circuit 232-A, each switch 266 may remain in the open state until one of the safety switches 30 opens. When this happens, the processor 40 may utilize a search-type algorithm to close a successive one of the switches 266 in turn until the differential voltage equals approximately zero Volts. The processor 40 may determine the distance from a reference point to, the location of, or the identity of, the tower 12 whose safety switch 30 is open according to which one of the switches 266 was closed to bring the differential voltage to approximately zero Volts, as measured by the voltmeter 260. For example, if the first switch 266-1 is closed, then the (first) safety switch 30 at the first tower 12A is open. If the second switch 266-2 is closed, then the (second) safety switch 30 at the second tower 12B is open and so forth. Alternatively, the processor 40 may use the inductance value of the reference inductor 250 at the closed switch 266 as an input to one or more mathematical equations or a lookup table to determine the distance from a reference point to, the location of, or the identity of, the tower 12 whose safety switch 30 is open.

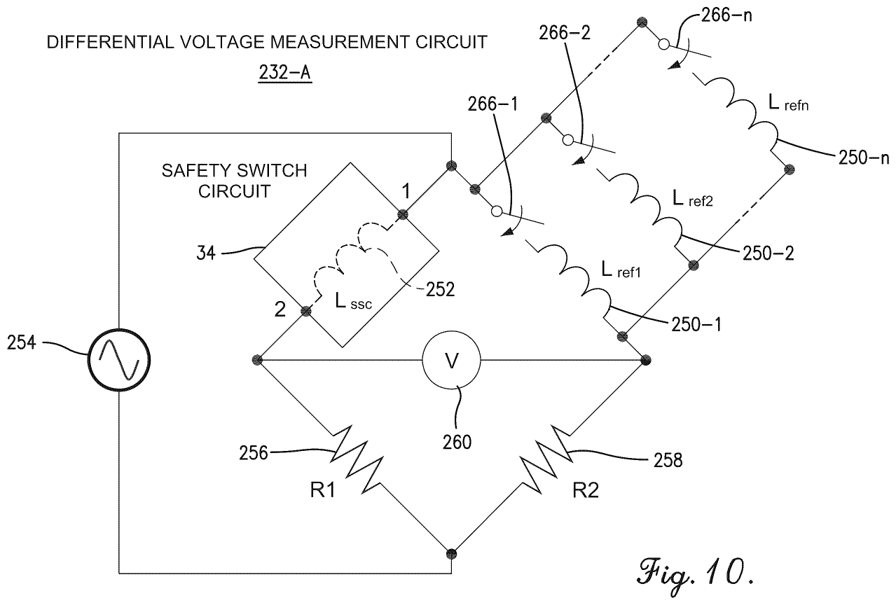

FIG. 11 depicts a listing of at least a portion of the steps of an exemplary method 400 for identifying an open safety switch 30 in an irrigation system 10, which may include a distance from a differential voltage measurement circuit 32-A, 132-A, 232-A to the open safety switch 30, a location of the open safety switch 30, and/or an identifier, such as an ordinal number, of a tower 12 associated with the open safety switch 30. Variations to the steps may be performed. The steps may be performed in the order shown in FIG. 11, or they may be performed in a different order. Furthermore, some steps may be performed concurrently as opposed to sequentially. In addition, some steps may be optional or may not be performed.

Referring to step 401, an impedance cable 48 is positioned in proximity to a safety switch cable 44 that electrically connects a plurality of safety switches 30 to one another to form a safety switch circuit 34. The irrigation system 10 includes at least a plurality of spaced-apart, motorized, and self-propelled towers 12 which support a fluid-carrying conduit 20 and sprayer system that sprays the fluid on one or more crops. Between each adjacent pair of towers 12 is a successive one of a plurality of sections of the conduit 20, wherein each adjacent pair of conduit sections is coupled with a successive one of a plurality of joints that is flexible.

Each safety switch 30 is embodied by a single-pole, single-throw (SPST) type switch, or any type of switch that includes a first terminal and a second terminal with a moveable contact providing electrical connection between the terminals in a closed position and no electrical connection in an open position. The safety switch 30 is closed when the alignment angle between the two sections of the conduit 20 joined at the associated tower 12 is below or equal to a safety threshold value and open when alignment angle is above the safety threshold value. The safety switch 30 may be implemented as a limit switch that is integrated in a mechanical assembly which includes a rotating cam mechanically coupled to the conduit 20 at the joint where two sections of the conduit 20 are connected. The cam rotates in response to the rotation of the outward section of the conduit 20 with respect to the inward section of the conduit 20, and thus the angular position of the cam represents the alignment angle between the two sections of the conduit 20. Rotation of the cam beyond the safety threshold angle, in either the clockwise direction or the counter clockwise direction, opens the safety switch 30.

Each of the safety switches 30 is electrically connected to the safety signal source 42 through the switch cable 44 and a return cable 46, as shown in FIG. 2. The switch cable 44 includes a plurality of sections, wherein a first section electrically connects the first port of the safety signal source 42 to the safety switch 30 at the first tower 12A. A successive one of other sections of the switch cable 44 electrically connects each successive adjacent pair of safety switches 30 to one another so that all of the safety switches 30 are electrically connected in series. The return cable 46 electrically connects the safety switch 30 at the next to the last tower 12N to the second port of the safety signal source 42. The safety switches 30, the switch cable 44, and the return cable 46 form an electrically conductive closed circuit path when all of the safety switches 30 are closed, which may be known as a “normal state”.

Referring to FIG. 2, the safety switches 30 and the switch cable 44 in combination with the impedance cable 48 form the safety switch circuit 34. The impedance cable 48 is an electrically conductive cable that extends from the central controller 14 (typically located at the center pivot 16) to the next to the last tower 12N and positioned in general proximity to the switch cable 44. The impedance cable 48 may be utilized for other control purposes when the irrigation machine is running, such as FWD, REV, % SPEED, End Gun1 and End Gun2 commands.

Referring to step 402, an alternating current (AC) voltage is applied to the safety switch circuit 34 and a reference load. The AC voltage is output by a voltage source 54, 154, 254, which is a component of the differential voltage measurement circuit 32-A, 132-A, 232-A. Referring to FIGS. 8 and 9, the differential voltage measurement circuit 32-A, 132-A includes the voltage source 54, 154, a first resistor 56, 156, a second resistor 58, 158, a reference capacitor 50-A, 150-A, and a safety switch circuit capacitor 52, 152. Various embodiments of the differential voltage measurement circuit 132 also include a safety switch circuit resistor 162 and a reference resistor 164-A, as shown in FIG. 9. Referring to FIG. 10, the differential voltage measurement circuit 232 includes the voltage source 254, a first resistor 256, a second resistor 258, a reference inductor 250-A, a plurality of safety switch circuit inductors 252, and a plurality of switches 266.

The voltage source 54, 154 is a varying voltage source, such as an alternating current (AC) voltage source formed from known electric power supplies which output sine wave voltage with a selectively specified frequency and amplitude or a direct current (DC) square wave voltage source with a selectively specified frequency and amplitude. Exemplary embodiments of the voltage source 54, 154 output AC voltage with a value greater than 12 VAC and an oscillating frequency that ranges between approximately 60 Hertz (Hz) and approximately 400 Hz, wherein 240 Hz is optimal. The first resistor 56, 156 and the second resistor 58, 158 typically have the same selectively specified resistance value. The reference capacitor 50-A, 150-A, which forms the reference load, has an adjustable capacitance value. The safety switch circuit capacitor 52, 152 is a virtual capacitor formed by the safety switch circuit 34, that is, the switch cable 44, the safety switches 30, and the impedance cable 48, which in combination also forms a safety switch circuit load. Its capacitance value varies according to, or is determined by, the position or ordinal number of, or a distance from a reference, or measurement, point to, the tower 12 having the open safety switch 30, wherein, generally a higher ordinal number results in a greater capacitance and vice-versa. (The capacitance value of the safety switch circuit capacitor 52, 152 is a maximum when all safety switches 30 are closed.) For example, if the irrigation system 10 includes eleven (11) towers 12 and ten (10) safety switches 30, the capacitance value of the safety switch circuit capacitor 52, 152 is greater when the ninth safety switch 30 is open compared to the second safety switch 30 being open.

The safety switch circuit resistor 162 is a virtual resistor formed by the safety switch circuit 34, that is, the switch cable 44, the safety switches 30, and the impedance cable 48. An impedance value of the capacitor and resistor combination 152, 162 varies according to, or is determined by, the position or ordinal number of, or the distance from a reference, or measurement, point to, the tower 12 having the open safety switch 30, wherein, generally a higher ordinal number results in a greater impedance and vice-versa. (The impedance value of the capacitor and resistor combination 152, 162 is a maximum when all safety switches 30 are closed.) For example, if the irrigation system 10 includes eleven (11) towers 12 and ten (10) safety switches 30, the impedance value of the capacitor and resistor combination 152, 162 is greater when the ninth safety switch 30 is open compared to the second safety switch 30 being open. The reference resistor 164-A has an adjustable resistance value. In various embodiments, the reference load includes the reference capacitor 50-A, 150-A and the reference resistor 164-A.

In the differential voltage measurement circuit 232-A, the voltage source 254 is a varying voltage source, such as an alternating current (AC) voltage source formed from known electric power supplies which output sine wave voltage with a selectively specified frequency and amplitude or a direct current (DC) square wave voltage source with a selectively specified frequency and amplitude. Exemplary embodiments of the voltage source 254 output AC voltage with a value greater than 12 VAC and an oscillating frequency that ranges between approximately 60 Hertz (Hz) and approximately 400 Hz, wherein 240 Hz is optimal. The first resistor 256 and the second resistor 258 typically have the same selectively specified resistance value. Each reference inductor 250 has a unique inductance value, wherein the inductance value may be roughly equal to the inductance value of the safety switch circuit inductor 252 when each successive safety switch 30 is open. For example, the reference inductor 250-1 may have an inductance value roughly equal to the inductance value of the safety switch circuit inductor 252 when the (first) safety switch 30 at the first tower 12A is open. The reference inductor 250-2 may have an inductance value roughly equal to the inductance value of the safety switch circuit inductor 252 when the (second) safety switch 30 at the second tower 12B is open and so forth. Alternatively, each reference inductor 250 may have an inductance value that is selected in order to provide a range of different inductance values. Each switch 266 is an SPST or toggle type electrical switch having an open state or a closed state, wherein the state is electronically controlled by the processor 40 through one or more control signals. Each switch 266 is electrically connected in series with a successive one of the inductors 250. And, each switch 266 and inductor 250 combination is electrically connected in parallel with the other switch 266 and inductor 250 combinations.

The safety switch circuit inductor 252 is a virtual inductor formed by the safety switch circuit 34, that is, the switch cable 44, the safety switches 30, and the impedance cable 48. In other words, the safety switch circuit 34 is modeled as the safety switch circuit inductor 252. Its inductance value varies according to, or is determined by, the position or ordinal number of, or the distance from a reference, or measurement, point to, the tower 12 having the open safety switch 30, wherein generally a higher ordinal number results in a greater inductance and vice-versa. (The inductance value of the safety switch circuit inductor 252 is a maximum when all safety switches 30 are closed.) For example, if the irrigation system 10 includes eleven (11) towers 12 and ten (10) safety switches 30, the inductance value of the safety switch circuit inductor 252 is greater when the ninth safety switch 30 is open compared to the second safety switch 30 being open.

In the differential voltage measurement circuit 32-A, the safety switch circuit 34 is modeled as the safety switch circuit capacitor 52. In the differential voltage measurement circuit 132-A, the safety switch circuit 34 is modeled as the safety switch circuit capacitor 152 in combination with the safety switch circuit resistor 162. In the differential voltage measurement circuit 232-A, the safety switch circuit 34 is modeled as the safety switch circuit inductor 252.

Referring to step 403, a differential voltage between a voltage drop across the safety switch circuit 34 and a voltage drop across the reference load is measured. The differential voltage measurement circuit 32-A, 132-A, 232-A further includes a voltmeter 60, 160, 260, or voltage sensing circuitry, which measures the voltage from the connection between the safety switch circuit 34 and the first resistor 56, 156, 256 to the connection between the reference load and the second resistor 58, 158, 258. The voltmeter 60, 160, 260, being connected in this fashion, is configured to measure a difference in voltage drop across the reference load and the safety switch circuit 34.

Referring to steps 404 and 405, an electrical characteristic of the reference load is changed or adjusted in order for the differential voltage to equal approximately zero Volts, as measured by the voltmeter 60, 160, 260. For the differential voltage measurement circuit 32-A, 132-A, the processor 40 may utilize a search-type algorithm to increase or decrease the capacitance value or the capacitance and resistance values of the reference capacitor 50 and the reference capacitor 150 and reference resistor 164, respectively, until the differential voltage measurement is approximately zero Volts, as measured by the voltmeter 60, 160. The processor 40 also records the amount by which the capacitance value or the capacitance and resistance values of the reference capacitor 50 and the reference capacitor 150 and reference resistor 164, respectively, is/are changed. The processor 40 may use the amount of change as an input to one or more mathematical equations or a lookup table to determine a distance from a reference point to, a location of, or an identity of, the tower 12 whose safety switch 30 is open.

For the differential voltage measurement circuit 232-A, each switch 266 may remain in the open state until one of the safety switches 30 opens. When this happens, the processor 40 may utilize a search-type algorithm to close a successive one of the switches 266 in turn until the differential voltage equals approximately zero Volts, as measured by the voltmeter 260. The processor 40 may determine the distance from a reference point to, the location of, or the identity of, the tower 12 whose safety switch 30 is open according to which one of the switches 266 was closed to bring the differential voltage to approximately zero Volts, as measured by the voltmeter 260. For example, if the first switch 266-1 is closed, then the (first) safety switch 30 at the first tower 12A is open. If the second switch 266-2 is closed, then the (second) safety switch 30 at the second tower 12B is open and so forth. Alternatively, the processor 40 may use the inductance value of the reference inductor 250 at the closed switch 266 as an input to one or more mathematical equations or a lookup table to determine the distance from a reference point to, the location of, or the identity of, the tower 12 whose safety switch 30 is open.

The bridge configuration electronic circuits of the differential voltage measurement circuits 32, 32-A, 132, 132-A, 232, 232-A are merely exemplary and other electronic circuit architectures, including other bridge configurations, could be utilized to determine the distance from a reference point to, the location of, or the identity of, the tower 12 whose safety switch 30 is open.

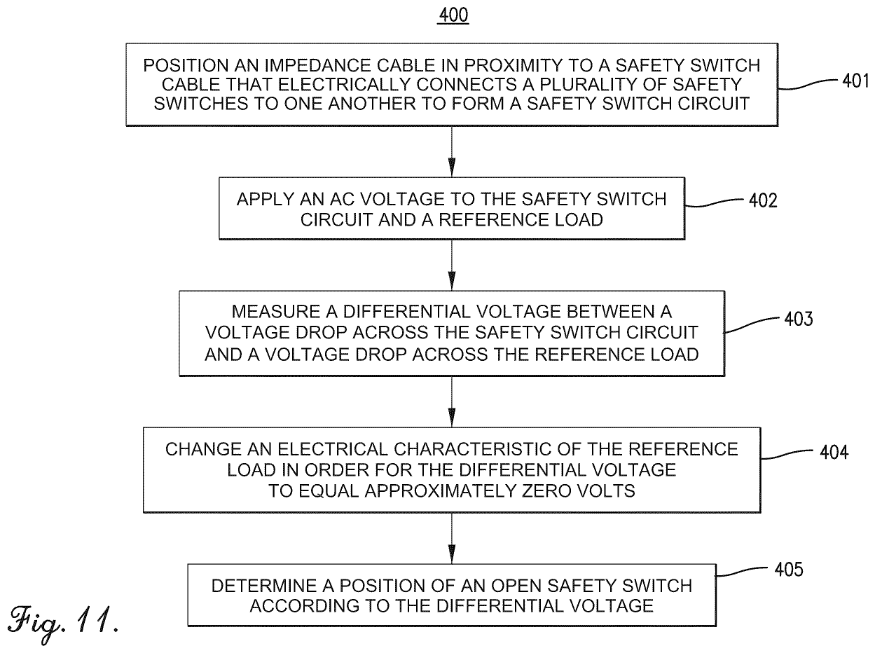

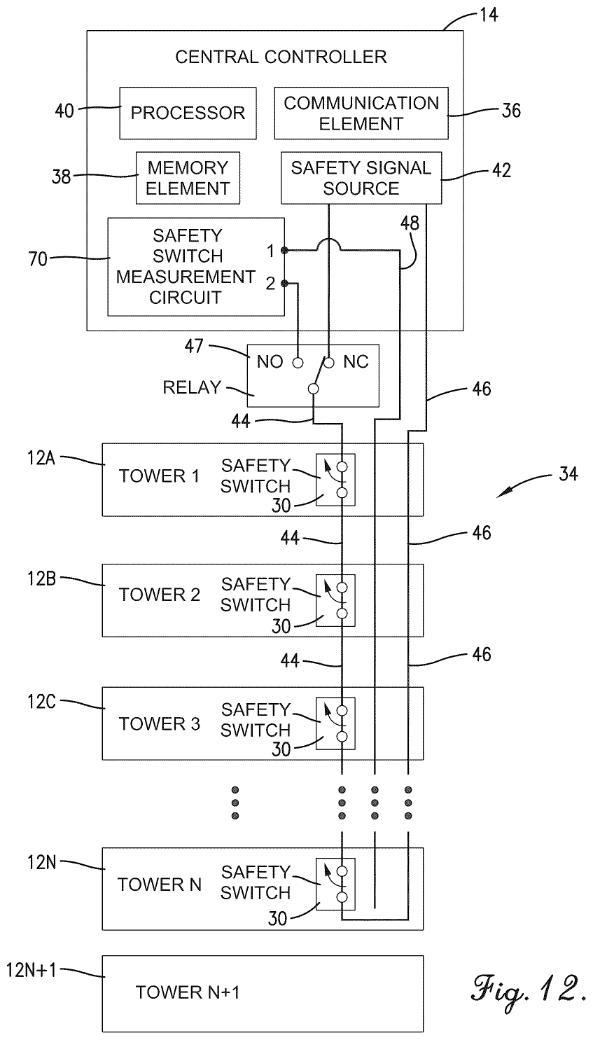

Referring to FIG. 12, in other embodiments of the current invention, the central controller 14 includes a safety switch measurement circuit 70 which measures various electrical characteristics of the safety switch circuit 34. The safety switch measurement circuit 70 is in electronic communication with the processor 40, the memory element 38, and the communication element 36. Referring to FIG. 13, one embodiment of the safety switch measurement circuit 70-1 includes a frequency domain reflectometry measurement in which the safety switch measurement circuit 70-1 determines a resonant frequency of the safety switch circuit 34 by sweeping a frequency of an electronic signal applied to the safety switch circuit 34 and determining the frequency at which the voltage of the safety switch circuit 34 is a maximum value. The safety switch measurement circuit 70-1 includes a frequency generator 302 and a signal processor 304. The safety switch measurement circuit 70-1 includes a first port 1 electrically connected to the impedance cable 48 and a second port 2 electrically connected to the relay 47 which is capable of switching the electrical connection of the second port 2 to the switch cable 44.

The frequency generator 302 generates a first electronic signal having a variable frequency. The frequency generator 302 includes a first terminal electrically connected to the first port 1, and a second terminal electrically connected to the second port 2. The frequency generator 302 also includes a waveform generator wherein the waveform may be a sine wave, a square wave, a triangle wave, or the like whose amplitude and frequency are controlled. Typically, the frequency of the first electronic signal (waveform) is swept, that is, varied (increased or decreased) from one frequency value to another frequency value. For example, the frequency of the first electronic signal may have a value that starts in the tens of Hertz and is varied (swept) to a value in the tens of kiloHertz.

The signal processor 304 measures an electrical characteristic of the first electronic signal, such as voltage and/or current, and makes a determination on whether all of the safety switches 30 are closed or whether at least one safety switch 30 is open, and if so, makes a determination on the location of, or the identity of, the tower 12 whose safety switch 30 is open. The signal processor 304 includes a first terminal electrically connected to the first port 1, and a second terminal electrically connected to the second port 2. The signal processor 304 may additionally include an ADC to convert analog voltages (such as by sampling) between the switch cable 44 and the impedance cable 48 to a stream of digital data values in binary form. The signal processor 304 may further include a processor, microprocessor, DSP, or the like to analyze the data and determine when the data values are at a maximum. The signal processor 304 may additionally have electronic communication with the frequency generator 302 and receive an indication of the frequency of the waveform of the first electronic signal output by the frequency generator 302. In addition, or instead, the signal processor 304 may measure or determine the frequency of the waveform of the first electronic signal output by the frequency generator 302 itself. More broadly, the signal processor 304 may measure or determine the frequency of any electronic signal across its terminals. In certain embodiments, the functions of the signal processor 304 may be performed by the processor 40 of the central controller 14.

The safety switch measurement circuit 70-1 may operate as follows. During a setup phase, when it is known that all of the safety switches 30 are closed and the relay 47 is set to electrically connect the second port 2 to the switch cable 44, the frequency generator 302 outputs the first electronic signal and sweeps or varies the frequency of the signal. The signal processor 304 determines data values representing the level of the voltage and determines when the data values are at a maximum. It is possible that the signal processor 304 may determine multiple maxima with approximately the same data value as a result of one or more harmonics of a fundamental resonant frequency. The signal processor 304 either receives the frequency value at the amplitude maximum, or it determines the frequency, which is the base resonant frequency of the safety switch circuit 34—that is, with all safety switches 30 closed. The signal processor 304 stores the base resonant frequency value in the memory element 38. When one of the safety switches 30 opens, the resonant frequency of the safety switch circuit 34 changes as a function of the length of the switch cable 44 to the tower 12 with the open switch 30. For example, the resonant frequency has a first value when the first safety switch 30 is open, a second value when the second safety switch 30 is open, and so forth, with each frequency value varying according to the length of the switch cable 44 from the central controller 14, or the center pivot 16, to the tower 12 with the open safety switch 30.

When it is determined that one of the safety switches 30 has opened and the processor 40 shuts down the operation of the irrigation system 10, the processor 40 also instructs the safety switch measurement circuit 70-1 to operate. The frequency generator 302 outputs the first electronic signal and sweeps or varies the frequency of the signal. The signal processor 304 determines data values representing the level of the voltage and determines when the data values are at a maximum. The signal processor 304 either receives the frequency value at the amplitude maximum, or it determines the frequency, i.e., the resonant frequency. The signal processor 304 either calculates the length of the switch cable 44 (such as by solving a mathematical equation with the resonant frequency as an input) or retrieves the length from a lookup table using the resonant frequency as a key/input. Having the length of the switch cable 44, the signal processor 304 then determines the identity or location of the tower 12 with the open safety switch 30. The signal processor 304 communicates the identity or location of the tower 12 with the open safety switch 30 to the processor 40 which outputs an alert as described above. In other embodiments, the signal processor 304 communicates the resonant frequency to the processor 40 which then determines the identity or location of the tower 12 with the open safety switch 30 and outputs an alert.

Referring again to FIG. 13, another embodiment of the safety switch measurement circuit 70-2, configured to perform amplitude domain reflectometry, includes substantially the same components as for the safety switch measurement circuit 70-1, that is, the frequency generator 302 and the signal processor 304. Except, with the safety switch measurement circuit 70-2, the components operate differently.

The frequency generator 302 outputs a periodic waveform second electronic signal which has a fixed amplitude and a fixed frequency, although the waveform may be selected from a sine wave, a square wave, a triangle wave, or the like. The second electronic signal is output to the safety switch circuit 34. The second electronic signal may reflect from the components of the safety switch circuit 34, wherein the characteristics of the reflection, such as the amplitude and the phase shift, may vary according to, or be determined by, an impedance of the safety switch circuit 34. The reflection, which may have the amplitude difference and the phase shift, interacts with the second electronic signal to create a first composite electronic signal, whose characteristics also vary according to the impedance of the safety switch circuit 34. The signal processor 304 measures the amplitude of the first composite electronic signal, which is the voltage at the first port 1 and the second port 2. When all of the safety switches 30 are closed, the impedance of the safety switch circuit 34 has a first value and thus the amplitude of the first composite electronic signal has a first value. When one of the safety switches 30 is open, the impedance of the safety switch circuit 34 has a second value that varies according to the position, the location, or the identification of the tower 12 which has the open safety switch 30. Accordingly, the amplitude of the first composite electronic signal has a second value that varies according to the position, the location, or the identification of the tower 12 which has the open safety switch 30.

The safety switch measurement circuit 70-2 may operate as follows. When it is determined that one of the safety switches 30 has opened and the processor 40 shuts down the operation of the irrigation system 10, the processor 40 also instructs the safety switch measurement circuit 70-2 to operate. The frequency generator 302 outputs the second electronic signal, and the signal processor 304 measures the amplitude of the first composite electronic signal. The signal processor 304 either calculates the position, the location, or the identification of the tower 12 which has the open safety switch 30 (such as by solving a mathematical equation with the amplitude of the composite electronic signal as an input) or retrieves the position, the location, or the identification of the tower 12 which has the open safety switch 30 from a lookup table using the amplitude of the first composite electronic signal as a key/input. The signal processor 304 communicates the position, the location, or the identification of the tower 12 with the open safety switch 30 to the processor 40 which outputs an alert as described above. In other embodiments, the signal processor 304 communicates the amplitude of the first composite electronic signal to the processor 40 which then determines the position, the location, or the identification of the tower 12 with the open safety switch 30 and outputs an alert.

Referring again to FIG. 13, another embodiment of the safety switch measurement circuit 70-3, configured to perform a quantified phase shift measurement, includes substantially the same components as for the safety switch measurement circuits 70-1, 70-2, that is, the frequency generator 302 and the signal processor 304. Except, with the safety switch measurement circuit 70-3, the components operate differently.

The frequency generator 302 outputs a periodic waveform third electronic signal which has a fixed amplitude and a fixed frequency, although the waveform may be selected from a sine wave, a square wave, a triangle wave, or the like. The third electronic signal is output to the safety switch circuit 34. The third electronic signal may reflect from the components of the safety switch circuit 34, wherein the characteristics of the reflection, such as the amplitude and the phase shift, may vary according to, or be determined by, an impedance of the safety switch circuit 34. The reflection, which may have the amplitude difference and the phase shift, interacts with the third electronic signal to create a second composite electronic signal, whose characteristics also vary according to the impedance of the safety switch circuit 34. The signal processor 304 measures the phase shift, or time delay, of the second composite electronic signal, which is the voltage at the first port 1 and the second port 2. When all of the safety switches 30 are closed, the impedance of the safety switch circuit 34 has a first value and thus the phase shift of the second composite electronic signal has a first value. When one of the safety switches 30 is open, the impedance of the safety switch circuit 34 has a second value that varies according to the position, the location, or the identification of the tower 12 which has the open safety switch 30. Accordingly, the phase shift of the second composite electronic signal has a second value that varies according to the position, the location, or the identification of the tower 12 which has the open safety switch 30.

The safety switch measurement circuit 70-3 may operate as follows. When it is determined that one of the safety switches 30 has opened and the processor 40 shuts down the operation of the irrigation system 10, the processor 40 also instructs the safety switch measurement circuit 70-3 to operate. The frequency generator 302 outputs the third electronic signal, and the signal processor 304 measures the phase shift of the second composite electronic signal. The signal processor 304 either calculates the position, the location, or the identification of the tower 12 which has the open safety switch 30 (such as by solving a mathematical equation with the amplitude of the composite electronic signal as an input) or retrieves the position, the location, or the identification of the tower 12 which has the open safety switch 30 from a lookup table using the phase shift of the second composite electronic signal as a key/input. The signal processor 304 communicates the position, the location, or the identification of the tower 12 with the open safety switch 30 to the processor 40 which outputs an alert as described above. In other embodiments, the signal processor 304 communicates the phase shift of the second composite electronic signal to the processor 40 which then determines the position, the location, or the identification of the tower 12 with the open safety switch 30 and outputs an alert.

Referring again to FIG. 13, another embodiment of the safety switch measurement circuit 70-4, configured to determine an equivalent series resistance of the safety switch circuit 34, includes substantially the same components as for the safety switch measurement circuits 70-1, 70-2, 70-3, that is, the frequency generator 302 and the signal processor 304. However, with the safety switch measurement circuit 70-4, the components operate differently.

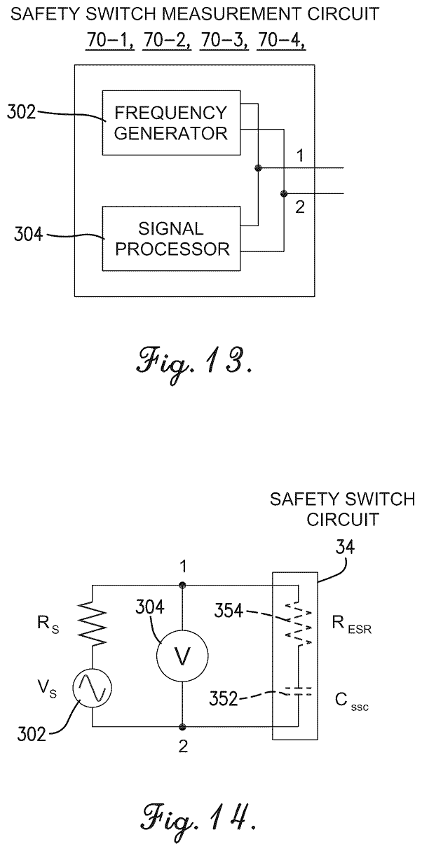

Referring to FIG. 14, the safety switch circuit 34 is modeled as the safety switch circuit capacitor 352 that has a series resistor 354. The frequency generator 302 is utilized as a voltage source Vs that includes a source resistor Rs. The signal processor 304 is utilized as a voltmeter configured to measure the voltage at the first port 1 and the second port 2, which is the voltage of the safety switch circuit 34. To characterize the safety switch circuit 34 with all of the safety switches 40 closed, the frequency generator 302 outputs a fourth electronic signal having a fixed frequency and a fixed (known) current amplitude. In order to minimize the capacitive reactance contribution of the safety switch circuit capacitor 352 to the impedance of the safety switch circuit 34, the frequency generator 302 outputs the fourth electronic signal to have a high frequency—in the range of 100 kiloHertz or greater. Accordingly, at the high frequency, the value of the impedance of the safety switch circuit 34 is dominated by the resistance value of the resistor 354. In addition, the frequency generator 302 outputs the fourth electronic signal for a period of time that is less than a charge time of the safety switch circuit capacitor 352 so that the safety switch circuit capacitor 352 does not fully charge (which may be on the order of microseconds or milliseconds). The amplitude of the voltage at the first port 1 and the second port 2 is measured by the signal processor 304. The signal processor 304 then calculates or determines the resistance value of the resistor 354 as the measured voltage divided by the known current. The resistance value of the resistor 354 is the equivalent series resistance of the safety switch circuit 34 with all of the safety switches 30 closed. The equivalent series resistance has a value that varies according to the position or the location of the open safety switch 30.

The safety switch measurement circuit 70-4 may operate as follows. When it is determined that one of the safety switches 30 has opened and the processor 40 shuts down the operation of the irrigation system 10, the processor 40 also instructs the safety switch measurement circuit 70-4 to operate. The frequency generator 302 outputs the fourth electronic signal, and the signal processor 304 measures the amplitude of the voltage at the first port 1 and the second port 2. The signal processor 304 calculates the resistance of the series resistor 354, which is the equivalent series resistance of the safety switch circuit 34. The signal processor 304 then determines the position, the location, or the identification of the tower 12 which has the open safety switch 30 such as by solving a mathematical equation using the resistance as an input or by retrieving the position, the location, or the identification of the tower 12 which has the open safety switch 30 from a lookup table using the resistance as a key/input. The signal processor 304 communicates the position, the location, or the identification of the tower 12 with the open safety switch 30 to the processor 40 which outputs an alert as described above. In other embodiments, the signal processor 304 communicates the resistance to the processor 40 which then determines the position, the location, or the identification of the tower 12 with the open safety switch 30 and outputs an alert.

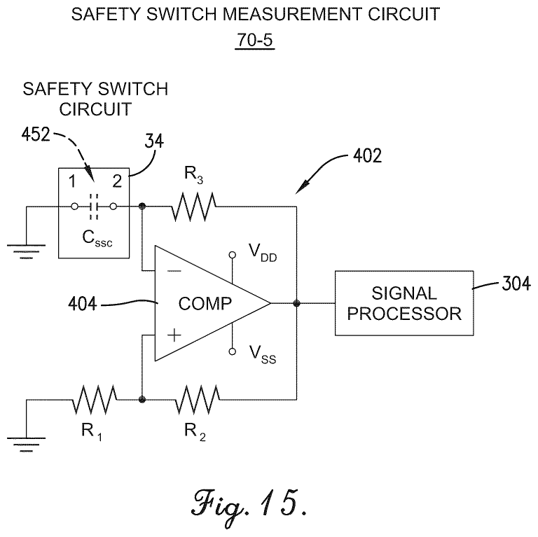

Referring to FIG. 15, another embodiment of the safety switch measurement circuit 70-5 is shown. The safety switch measurement circuit 70-5 includes a relaxation oscillator 402 and the signal processor 304. The relaxation oscillator 402 includes comparator 404, a first resistor R1, a second resistor R2, a third resistor R3, and the safety switch circuit capacitor 452. The comparator 404 includes a negative terminal, a positive terminal, and an output, all of which function or operate as are known with operational amplifiers. The comparator 404 is also electrically connected to a first voltage source VDD (typically positive) and a second voltage source VSS (typically negative). The resistors R1, R2, and R3 may all have the same resistance value. The first resistor R1 is electrically connected between electrical ground and the positive terminal. The second resistor R2 is electrically connected in a negative feedback configuration between the output and the positive terminal. The third resistor R3 is electrically connected in a negative feedback configuration between the output and the negative terminal. The safety switch circuit capacitor 452 is electrically connected between electrical ground and the negative terminal.

Briefly stated, the comparator 404 outputs a positive DC voltage if the voltage at the positive terminal is greater than the voltage at the negative terminal, and vice versa, the comparator 404 outputs a negative DC voltage if the voltage at the negative terminal is greater than the voltage at the positive terminal. When the comparator 404 outputs a positive voltage, the voltage at the positive terminal is VDD/2. The voltage at the negative terminal starts out at less than VDD/2, and the voltage across the safety switch circuit capacitor 452 attempts to increase (due to charge accumulation) to VDD. The voltage across the safety switch circuit capacitor 452 is also the voltage at the negative terminal. When the voltage at the negative terminal surpasses VDD/2, the voltage at the negative terminal is then greater than the voltage at the positive terminal, so the comparator 404 outputs a negative voltage. With a negative voltage at the output of the comparator 404, the voltage at the positive terminal decreases to VSS/2. The voltage at the negative terminal attempts to decrease from approximately VDD/2 to VSS (resulting in discharge of the safety switch circuit capacitor 452), which, given that VSS is a negative value, is less than VSS/2. As the voltage at the negative terminal decreases to less than VSS/2, the voltage at the positive terminal becomes greater than the voltage at the negative terminal and the output of the comparator 404 switches back to a positive voltage. The positive voltage at the output of the comparator 404 recharges the safety switch circuit capacitor 452 and increases the voltage at the negative terminal—which starts the cycle over again. The output of the comparator 404 oscillates between positive voltage and negative voltage, or more technically, between the approximate voltage of VDD and the approximate voltage of VSS, with a frequency that is determined by the capacitance of the safety switch circuit capacitor 452 and the resistance of the third resistor R3. Given that the resistance of the third resistor R3 is constant, the frequency of the periodic output of the comparator 404 varies according to changes in the capacitance of the safety switch circuit capacitor 452, which in turn varies according to the position, the location, or the identification of the tower 12 with the open safety switch 30. The signal processor 304 receives the output of the comparator 404 and determines the frequency of the oscillation.

The safety switch measurement circuit 70-5 may operate as follows. When it is determined that one of the safety switches 30 has opened and the processor 40 shuts down the operation of the irrigation system 10, the processor 40 also instructs the safety switch measurement circuit 70-5 to operate. The voltage sources VDD and VSS are activated and the comparator 404 outputs a positive voltage or a negative voltage, depending on the voltage of the safety switch circuit capacitor 452. The output of the comparator 404 oscillates between positive voltage and negative voltage, or between VSS and VDD, with a frequency that varies according to the capacitance of the safety switch circuit capacitor 452. The signal processor 304 determines the frequency of oscillation. The signal processor 304 then determines the position, the location, or the identification of the tower 12 which has the open safety switch 30 such as by solving a mathematical equation using the frequency as an input or by retrieving the position, the location, or the identification of the tower 12 which has the open safety switch 30 from a lookup table using the frequency as a key/input. The signal processor 304 communicates the position, the location, or the identification of the tower 12 with the open safety switch 30 to the processor 40 which outputs an alert as described above. In other embodiments, the signal processor 304 communicates the frequency to the processor 40 which then determines the position, the location, or the identification of the tower 12 with the open safety switch 30 and outputs an alert.

Throughout this specification, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the current invention can include a variety of combinations and/or integrations of the embodiments described herein.

Although the present application sets forth a detailed description of numerous different embodiments, it should be understood that the legal scope of the description is defined by the words of the claims set forth at the end of this patent and equivalents. The detailed description is to be construed as exemplary only and does not describe every possible embodiment since describing every possible embodiment would be impractical. Numerous alternative embodiments may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processor, may be implemented as special purpose or as general purpose. For example, the processor may comprise dedicated circuitry or logic that is permanently configured, such as an application-specific integrated circuit (ASIC), or indefinitely configured, such as an FPGA, to perform certain operations. The processor may also comprise programmable logic or circuitry (e.g., as encompassed within a general-purpose processor or other programmable processor) that is temporarily configured by software to perform certain operations. It will be appreciated that the decision to implement the processor as special purpose, in dedicated and permanently configured circuitry, or as general purpose (e.g., configured by software) may be driven by cost and time considerations.

Accordingly, the term “processor” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processor is temporarily configured (e.g., programmed), each of the processors need not be configured or instantiated at any one instance in time. For example, where the processor comprises a general-purpose processor configured using software, the general-purpose processor may be configured as respective different processors at different times. Software may accordingly configure the processor to constitute a particular hardware configuration at one instance of time and to constitute a different hardware configuration at a different instance of time.

Computer hardware components, such as communication elements, memory elements, processors, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods or routines described herein may be at least partially processor-implemented. For example, at least some of the operations of a method may be performed by one or more processors or processor-implemented hardware modules. The performance of certain of the operations may be distributed among the one or more processors, not only residing within a single machine, but deployed across a number of machines. In some example embodiments, the processors may be located in a single location (e.g., within a home environment, an office environment or as a server farm), while in other embodiments the processors may be distributed across a number of locations.

Unless specifically stated otherwise, discussions herein using words such as “processing”, “computing”, “calculating”, “determining”, “presenting”, “displaying”, or the like may refer to actions or processes of a machine (e.g., a computer with a processor and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises”, “comprising”, “includes”, “including”, “has”, “having”, or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the embodiments illustrated in the attached drawing figures, it is noted that equivalents may be employed and substitutions made herein without departing from the scope of the technology as recited in the claims.

Having thus described various embodiments of the technology, what is claimed as new and desired to be protected by Letters Patent includes the following:

1. An irrigation system comprising:
a plurality of towers, at least a portion of the towers including a successive one of a plurality of safety switches, each safety switch being either closed or open, the safety switch of each tower electrically connected to at least one safety switch of another tower; and
a central controller electrically connected to at least one of the safety switches, the central controller configured to:
measure a differential voltage between a safety switch circuit load formed in part by the safety switches and a reference load, and
determine, according to the differential voltage, at least one of a location of the open safety switch, a distance from a reference point, and an identifier of the tower associated with the open safety switch.

2. The irrigation system of claim 1, wherein the safety switch circuit load is formed by
the safety switches,
a switch cable including a plurality of sections that electrically connect the central controller to a first safety switch and the safety switches to one another, and
an impedance cable electrically connected to the central controller and extending from the central controller to one of the outer towers.

3. The irrigation system of claim 1, wherein the central controller includes, or is in electronic communication with, a differential voltage measurement circuit including
a voltage source configured to output a varying voltage;
the safety switch circuit load, the reference load, and two resistors electrically connected to one another to form a bridge circuit that is electrically connected to the voltage source; and
a voltmeter configured to measure the differential voltage.

4. The irrigation system of claim 3, wherein the differential voltage is measured from a first point between the safety switch circuit load and a first resistor to a second point between the reference load and a second resistor.

5. The irrigation system of claim 1, wherein the differential voltage varies according to a change in a capacitance of the safety switch circuit load.

6. The irrigation system of claim 1, wherein the differential voltage varies according to a change in an inductance of the safety switch circuit load.

7. The irrigation system of claim 1, wherein the safety switch circuit load is modeled as a first capacitor and the reference load includes a second capacitor.

8. The irrigation system of claim 1, wherein the safety switch circuit load is modeled as a first inductor and the reference load includes a second inductor.

9. The irrigation system of claim 1, wherein the safety switch circuit load is modeled as a first capacitor connected in series with a first resistor and the reference load includes a second capacitor electrically connected in parallel with a second resistor.

10. An irrigation system comprising:
a plurality of towers, at least a portion of the towers including a successive one of a plurality of safety switches, each safety switch being either closed or open, the safety switch of each tower electrically connected to at least one safety switch of another tower; and
a central controller electrically connected to at least one of the safety switches, the central controller including, or in electronic communication with, a differential voltage measurement circuit comprising:
a voltage source configured to output a varying voltage;
a safety switch circuit load formed in part by the safety switches, a reference load, and two resistors electrically connected to one another to form a bridge circuit that is electrically connected to the voltage source; and
a voltmeter configured to measure a differential voltage from a first point between the safety switch circuit load and a first resistor to a second point between the reference load and a second resistor;
wherein the central controller further includes a processor configured to determine, according to the differential voltage, at least one of a location of the open safety switch, a distance from a reference point, and an identifier of the tower associated with the open safety switch.

11. The irrigation system of claim 10, wherein the safety switch circuit load is formed by
the safety switches,
a switch cable including a plurality of sections that electrically connect the central controller to a first safety switch and the safety switches to one another, and
an impedance cable electrically connected to the central controller and extending from the central controller to one of the outer towers.

12. The irrigation system of claim 10, wherein the safety switch circuit load is modeled as a first component selected from the group including a first capacitor, a first inductor, and a second capacitor connected in series with a first resistor, and the reference load includes a second component selected from the group including a third capacitor, a second inductor, and a fourth capacitor electrically connected in parallel with a second resistor.

13. A method for determining a position of, or a distance to, an open safety switch in an irrigation system that includes a plurality of towers, at least a portion of the towers including a successive one of a plurality of safety switches, the method comprising:
positioning an impedance cable in proximity to a safety switch cable that electrically connects the safety switches to one another to form a safety switch circuit;
applying a varying voltage to the safety switch circuit and a reference load;
measuring a differential voltage between a voltage drop across the safety switch circuit and a voltage drop across the reference load; and
determining the position of, or the distance to, an open safety switch according to the differential voltage.

14. The method of claim 13, wherein the impedance cable is positioned to extend from a center pivot to one of the outer towers.

15. The method of claim 13, wherein the safety switch circuit includes the safety switches, a switch cable that includes a plurality of sections that electrically connect the differential voltage measurement circuit to a first safety switch and the safety switches to one another, and the impedance cable.

16. The method of claim 13, wherein the irrigation system includes a differential voltage measurement circuit which has a voltage source to apply the varying voltage and a voltmeter to measure the differential voltage.

17. The method of claim 16, wherein the differential voltage measurement circuit further includes the safety switch circuit, the reference load, and two resistors electrically connected to one another to form a bridge circuit that is electrically connected to the voltage source.

18. The method of claim 13, wherein the safety switch circuit is modeled as a first capacitor and the reference load includes a second capacitor.

19. The method of claim 13, wherein the safety switch circuit is modeled as a first inductor and the reference load includes a second inductor.

20. The method of claim 13, wherein the safety switch circuit is modeled as a first capacitor connected in series with a first resistor and the reference load includes a second capacitor electrically connected in parallel with a second resistor.
